(19) United States
(12) Patent Application Publication
(10) Pub. No.: US 2015/0262689 A1
(43) Pub. Date: Sep. 17, 2015

(54) NONVOLATILE SEMICONDUCTOR MEMORY DEVICE

(71) Applicant: KABUSHIKI KAISHA TOSHIBA, Tokyo (JP)

(72) Inventors: Toshifumi HASHIMOTO, Fujisawa Kanagawa (JP); Takuya FUTATSUYAMA, Yokohamashi Kanagawa (JP); Hiroyasu TANAKA, Yokkaichi Mie (JP)

(21) Appl. No.: 14/470,431

(22) Filed: Aug. 27, 2014

(30) Foreign Application Priority Data
Mar. 12, 2014 (JP) 2014-049430

(51) Int. Cl. G11C 16/26; G11C 5/06

(52) U.S. Cl. CPC G11C 16/26; G11C 5/06

(57) ABSTRACT

A nonvolatile semiconductor memory device includes a plurality of memory cells, a plurality of bit lines, each coupled to one of the memory cells, and a control circuit that performs a control for reading data from the first, second, and third memory cells such that when one of the first, second, and third memory cells is selected for reading, the other memory cells are not selected for reading.

### CROSS-REFERENCE TO RELATED APPLICATION

This application is based upon and claims the benefit of priority from Japanese Patent Application No. 2014-049430, filed Mar. 12, 2014, the entire contents of which are incorporated herein by reference.

### FIELD

Embodiments described herein relate generally to a nonvolatile semiconductor memory device.

### BACKGROUND

Recently, various three-dimensional nonvolatile semiconductor memory devices in which memory cells are stacked in a longitudinal direction have been developed.

### DESCRIPTION OF THE DRAWINGS

FIG. 1 is a block diagram illustrating a memory cell array and a sense amplifier according to a first embodiment.

FIG. 2 is a diagram schematically illustrating blocks in a region A in FIG. 1.

FIG. 3 is a cross-sectional view taken along line A-A in FIG. 2.

FIG. 4 is a cross-sectional view taken along line B-B in FIG. 2.

FIG. 5 is an equivalent circuit diagram of blocks according to the first embodiment.

FIG. 6 is a circuit diagram illustrating a memory string according to the first embodiment.

FIG. 7 is a block diagram illustrating a nonvolatile semiconductor memory device according to the first embodiment.

FIG. 8 is a circuit diagram illustrating a sense amplifier and a bit line driver according to the first embodiment.

FIGS. 9A and 9B are diagrams schematically illustrating a case where data is read in units of three bit lines that are adjacent in a four-line staggering pattern, according to the first embodiment.

FIG. 10A is a diagram illustrating a bit line contact capacitance generated when a bit line BLa in the present embodiment is read, FIG. 10B is a diagram illustrating a bit line contact capacitance generated when a bit line BLb in the present embodiment is read, and FIG. 10C is a diagram illustrating a bit line contact capacitance generated when a bit line BLc in the present embodiment is read.

FIGS. 11A and 11B are diagrams schematically illustrating a first comparative example in which data is read in units of two bit lines that are adjacent in a four-line staggering pattern.

FIG. 12A is a diagram illustrating a bit line contact capacitance generated when a bit line BLev in the first comparative example is read, and FIG. 12B is a diagram illustrating a bit line contact capacitance generated when a bit line BLod in the first comparative example is read.

FIG. 13 is a comparison diagram illustrating the bit line contact capacitances in the present embodiment and the bit line contact capacitances in the first comparative example.

FIG. 14 is a timing chart illustrating a read operation of data of a memory cell connected to a bit line according to the first embodiment.

FIG. 15 is a diagram schematically illustrating blocks of a first modification example in the region A in FIG. 1.

FIG. 16 is a block diagram illustrating a memory cell array of a second modification example.

FIG. 17(a) is a diagram schematically illustrating blocks in a region B in FIG. 16, and FIG. 17(b) is a diagram schematically illustrating blocks in a region C in FIG. 16.

FIG. 18 is a diagram schematically illustrating a case where data is read in units of three bit lines that are adjacent in a four-line staggering pattern according to a second embodiment.

FIG. 19A is a diagram illustrating a bit line contact capacitance generated when a bit line BLa in the present embodiment is read, FIG. 19B is a diagram illustrating a bit line contact capacitance generated when a bit line BLb in the present embodiment is read, and FIG. 19C is a diagram illustrating a bit line contact capacitance generated when a bit line BLc in the present embodiment is read.

FIG. 20 is a diagram schematically illustrating a second comparative example in which data is read in units of two bit lines that are adjacent in a four-line staggering pattern.

FIG. 21A is a diagram illustrating a bit line contact capacitance generated when a bit line BLev in the second comparative example is read, and FIG. 21B is a diagram illustrating a bit line contact capacitance generated when a bit line BLod in the second comparative example is read.

FIG. 22 is a comparison diagram illustrating the bit line contact capacitances in the present embodiment and the bit line contact capacitances in the second comparative example.

FIGS. 23A and 23B are diagrams schematically illustrating a case where data is read in units of four bit lines that are adjacent in a four-line staggering pattern according to a third embodiment.

FIG. 24A is a diagram illustrating a bit line contact capacitance generated when a bit line BLa in the present embodiment is read, FIG. 24B is a diagram illustrating a bit line contact capacitance generated when a bit line BLb in the present embodiment is read, FIG. 24C is a diagram illustrating a bit line contact capacitance generated when a bit line BLc in the present embodiment is read, and FIG. 24D is a diagram illustrating a bit line contact capacitance generated when a bit line in the present embodiment is read.

FIGS. 25A and 25B are diagrams schematically illustrating a third comparative example in which data is read in units of two bit lines that are adjacent in a four-line staggering pattern.

FIG. 26A is a diagram illustrating a bit line contact capacitance generated when a bit line BLev in the third comparative example is read, and FIG. 26B is a diagram illustrating a bit line contact capacitance generated when a bit line in the third comparative example is read.

FIG. 27 is a comparison diagram illustrating the bit line contact capacitances in the present embodiment and the bit line contact capacitances in the third comparative example.

FIG. 28 is a diagram schematically illustrating a block in a four-line staggering pattern according to a third modification example.

FIG. 29 is a diagram schematically illustrating a fourth modification example in which data is read in units of three bit lines that are adjacent in a three-line staggering pattern.

FIG. 30 is a diagram schematically illustrating a fifth modification example in which data is read in units of four bit lines that are adjacent in a four-line staggering pattern.

FIG. 31 is a diagram schematically illustrating blocks of a sixth modification example in the region A in FIG. 1.

FIG. 32 is a diagram schematically illustrating blocks of a seventh modification example in the region A in FIG. 1.

### DETAILED DESCRIPTION

The present embodiment now will be described more fully hereinafter with reference to the accompanying drawings, in which various embodiments are illustrated. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, may therefore, encompass both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” may, therefore, encompass both an orientation of above and below.

Embodiments are described herein with reference to cross sections and perspective illustrations that are schematic illustrations of embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

Exemplary embodiments described herein provide a nonvolatile semiconductor memory device capable of a read operation with high reliability.

According to one embodiment, a nonvolatile semiconductor memory device includes a plurality of memory cells, a plurality of bit lines, each coupled to one of the memory cells, and a control circuit that performs a control for reading data from the first, second, and third memory cells such that when one of the first, second, and third memory cells is selected for reading, the other memory cells are not selected for reading.

Hereinafter, exemplary embodiments will be described with reference to the accompanying drawings. In a nonvolatile semiconductor memory device, it is effective to arrange memory strings in a staggering pattern in consideration of the capacity of a memory chip, a page length, a block size, and the like. In the case of the memory strings of the staggering pattern, noise via capacitances of adjacent bit line contacts is received. If the amount of noise increases, reliability of a read operation is reduced, or a read time is prolonged, for example.

The nonvolatile semiconductor memory device according to the present embodiment is a three-dimensional nonvolatile semiconductor memory device in which memory strings having a memory cell in which memory cell transistors are stacked in a longitudinal direction are arranged in a staggering pattern. The nonvolatile semiconductor memory device according to the present embodiment is not limited to this case.

### First Embodiment

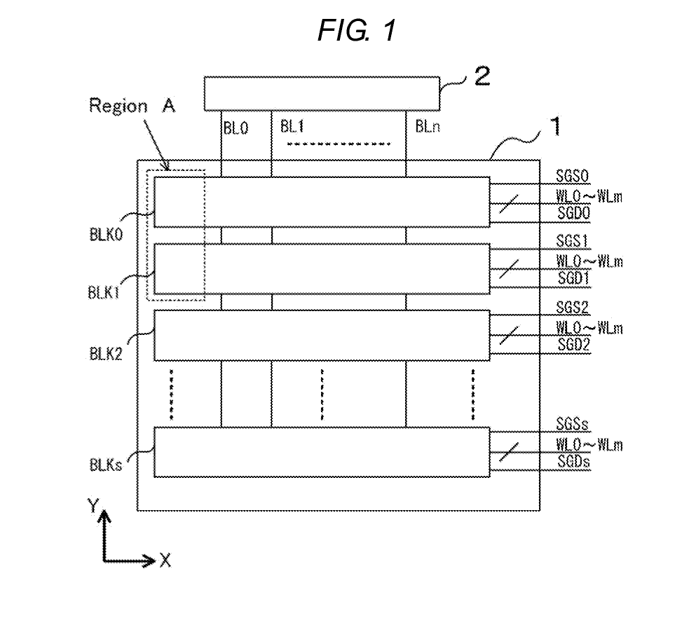

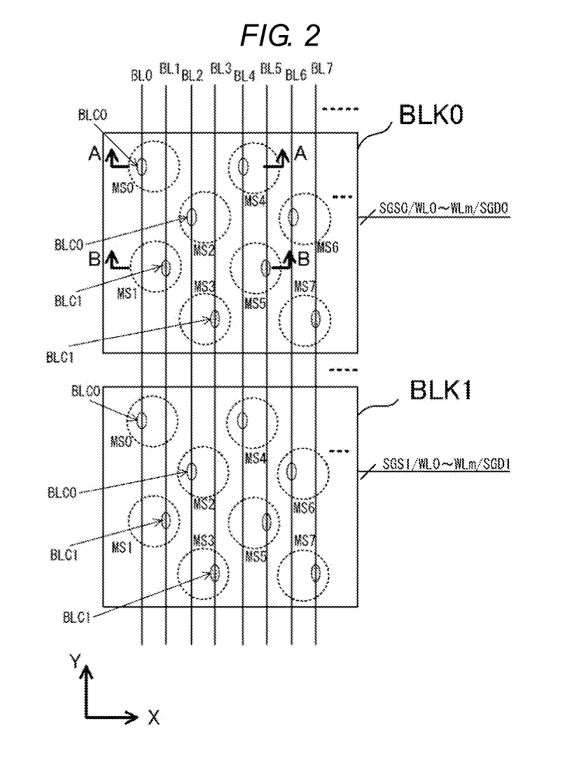

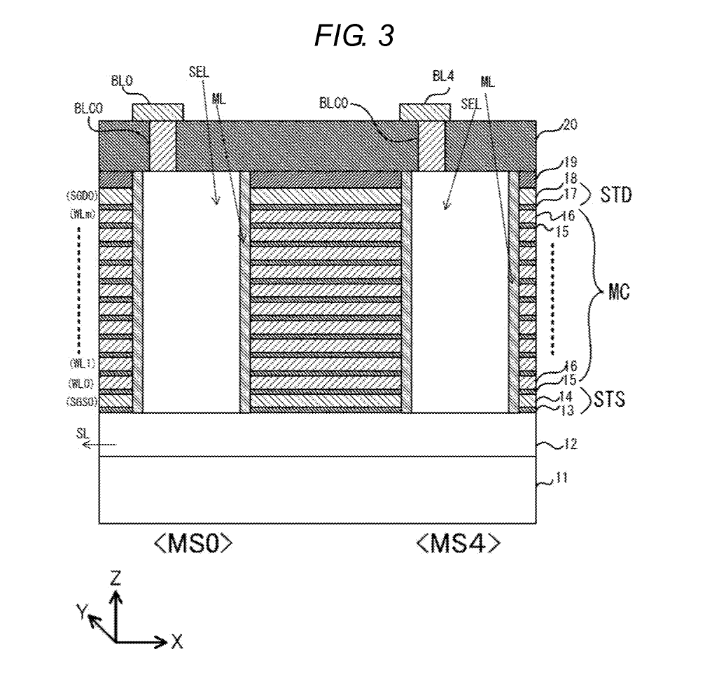

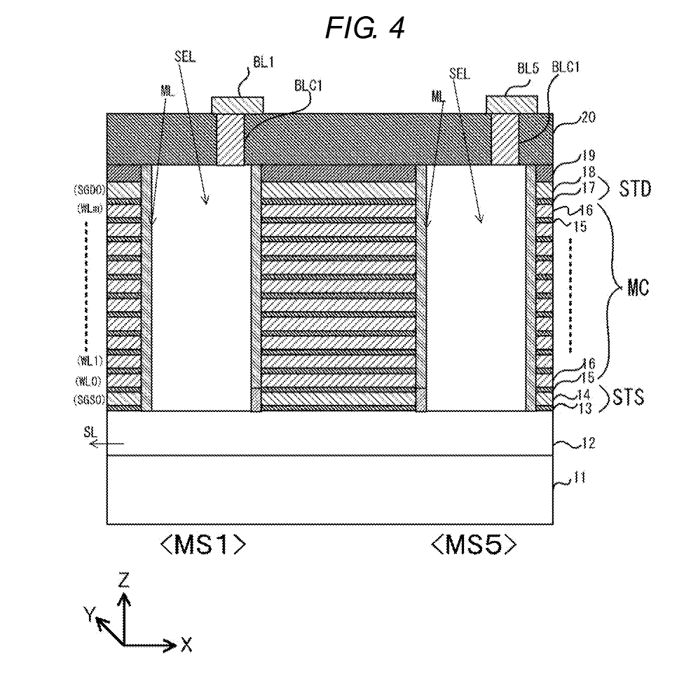

First, the nonvolatile semiconductor memory device according to the first embodiment will be described with reference to the accompanying drawings. FIG. 1 is a block diagram illustrating a memory cell array and a sense amplifier. FIG. 2 is a diagram schematically illustrating blocks in region A in FIG. 1. FIG. 3 is a cross-sectional view taken along line A-A in FIG. 2. FIG. 4 is a cross-sectional view taken along line B-B in FIG. 2. In the present embodiment, a plurality of memory strings are arranged in a K-line (K is an integer of 3 or more) staggering pattern, and data of memory cells connected to bit lines are sequentially read in units of adjacent L (L is an integer of 3 or more) bit lines. Specifically, a case where the value of K is 4 and the value of L is 3 will be described as an example.

As illustrated in FIG. 1, a memory cell array 1 includes blocks BLK0 to BLKs. The blocks BLK0 to BLKs extend parallel to each other in the X direction (a first direction), and are arranged along the Y direction (a second direction). A selector gate line SGS0, word lines WL0 to WLm and a selector gate line SGD0 are connected to the block BLK0. A selector gate line SGS1, the word lines WL0 to WLm and a selector gate line SGD1 are connected to the block BLK1. A selector gate line SGS2, the word lines WL0 to WLm and a selector gate line SGD2 are connected to the block BLK2. A selector gate line SGSs, the word lines WL0 to WLm (here, m is an integer of 2 or more) and a selector gate line SGDs are connected to block BLKs.

Bit lines BL0 to BLn extend parallel to each other in the Y direction (the second direction), and are arranged along the X direction (the first direction). The bit lines BL0 to BLn (n is an integer of 2 or more) connect the respective blocks BLK0 to BLKs to a sense amplifier 2. The sense amplifier 2 reads data of memory cells MC connected to the bit lines BL.

As illustrated in FIG. 2, for example, a plurality of memory strings MS are arranged in a four-line staggering pattern in the block BLK0 and the block BLK1. The plurality of memory strings MS have the same shape, and are connected to the bit lines BL through a bit line contact BLC0 or a bit line contact BLC1. The bit line contact BLC0 is provided on one side (for example, on the left side in the figure) in the X direction (the first direction). The bit line contact BLC1 is provided on the other side (for example, on the right side in the figure) in the X direction (the first direction). Since the expressions of one side (for example, on the left side in the figure) in the X direction (the first direction) and the other side (for example, on the right side in the figure) in the X direction (the first direction) are applied in the same manner in the embodiment, and thus, the expressions of (for example, on the left side in the figure) and (for example, on the right side in the figure) will not be repeated hereinafter.

Specifically, the bit line BL0 (a first bit line) is connected to the memory string MS0 that is a first memory string when seen from one side (for example, on the upper side in the figure) in the Y direction (the second direction) through the bit line contact BLC0 (a first bit line contact). Since the expression of one side (for example, on the upper side in the figure) in the Y direction (the second direction) is applied in the same manner in the embodiment, the expression of (for example, on the upper side in the figure) will not be repeated. The bit line BL1 (a second bit line) is connected to the memory string MS1 that is a third memory string when seen from one side in the Y direction (the second direction) through the bit line contact BLC1 (a second bit line contact). The bit line BL2 (a third bit line) is connected to the memory string MS2 that is a second memory string when seen from one side in the Y direction (the second direction) through the bit line contact BLC0 (the first bit line contact). The bit line BL3 (a fourth bit line) is connected to the memory string MS3 that is a fourth memory string when seen from one side in the Y direction (the second direction) through the bit line contact BLC1 (the second bit line contact). Since the bit line BL4 (a fifth bit line) and thereafter repeat the same arrangement, and thus, the description is not repeated.

As illustrated in FIG. 3, a semiconductor layer 12 is provided on a first main surface of a silicon substrate 11. The semiconductor layer 12 has a conductivity type different from the silicon substrate 11. Here, the semiconductor layer 12 is connected to a source line SL. The memory string MS0 and the memory string MS4 are separately disposed in the X direction (the first direction). The memory string MS0 and the memory string MS4 are provided on the first main surface of the semiconductor layer 12, and pass through the block BLK0 that is a stacked body in the Z direction in the figure (a third direction).

An insulating layer 13, a conductive layer 14, multiple stacks of an insulating layer 15 and a conductive layer 16, an insulating layer 17, a conductive layer 18, and an insulating layer 19 are stacked on the semiconductor layer 12 in the vicinity of the memory string MS0 and the memory string MS4. The memory string MS0 and the memory string MS4 are formed so that a semiconductor pillar SEL is provided on an inner portion thereof and a memory layer ML is provided on an outer portion thereof. The memory layer ML is formed of a plurality of insulating films having a charge trapping oxide film-nitride film-oxide film (ONO) structure.

In the memory string MS0 and the memory string MS4, a selection transistor STS, a memory cell MC in which memory cell transistors are stacked, and a selection transistor STD are formed in the Z direction (the third direction). The selection transistor STS is a transistor having a MONOS structure in which the conductive layer 14 is used as agate electrode. The memory cell transistor is a transistor having a MONOS structure in which the conductive layer 16 is used as agate electrode. The selection transistor STD is a transistor having a MONOS structure in which the conductive layer 18 is used as a gate electrode.

The bit line contact BLC0 is embedded in the insulating layer 20. The memory string MS0 is connected to the bit line BL0 through the bit line contact BLC0. The memory string MS4 is connected to the bit line BL4 through the bit line contact BLC0.

As illustrated in FIG. 4, the bit line contact BLC1 is embedded in the insulating layer 20. The memory string MS1 is connected to the bit line BL1 through the bit line contact BLC1. The memory string MS5 is connected to the bit line BL5 through the bit line contact BLC1.

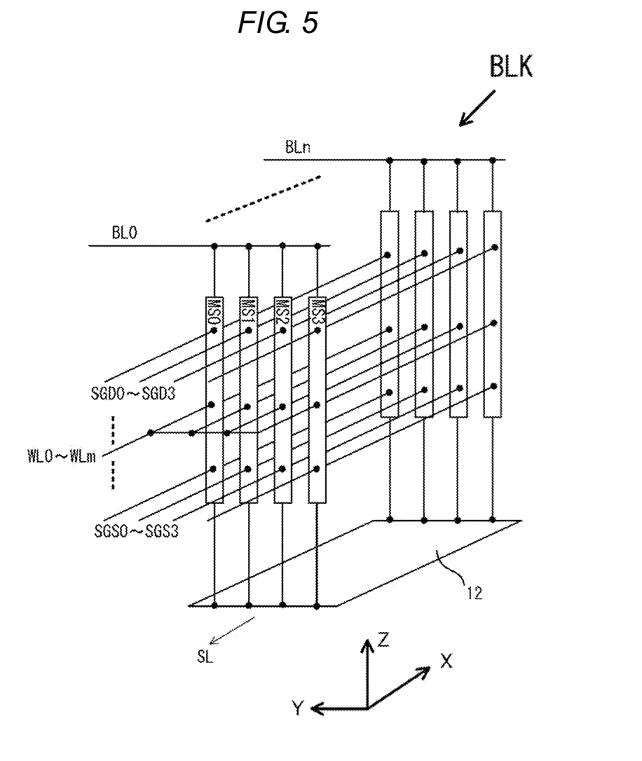

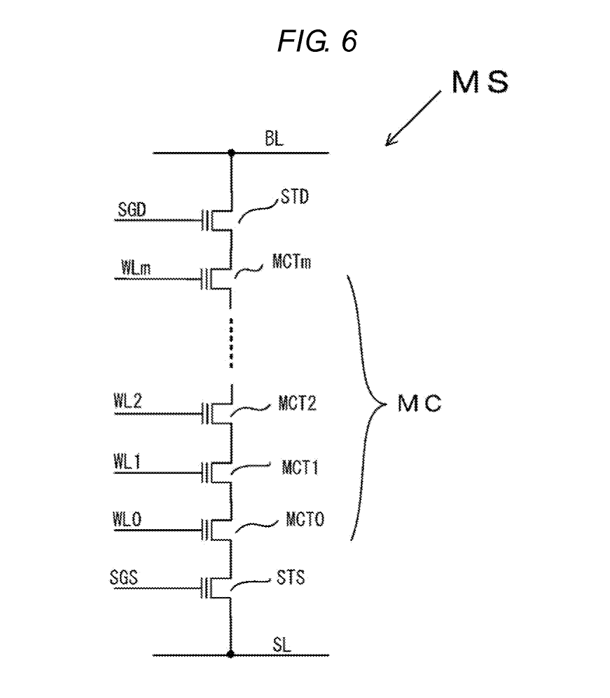

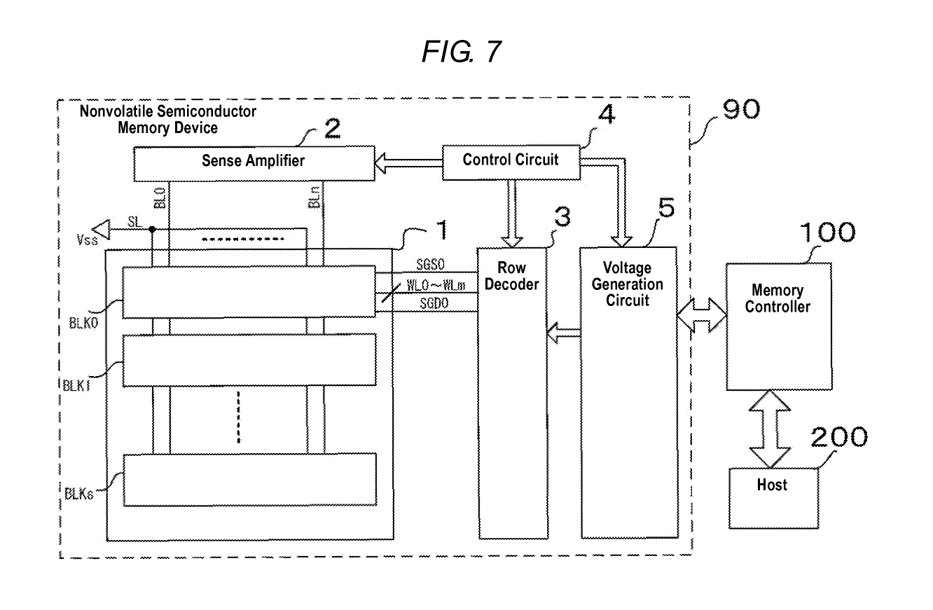

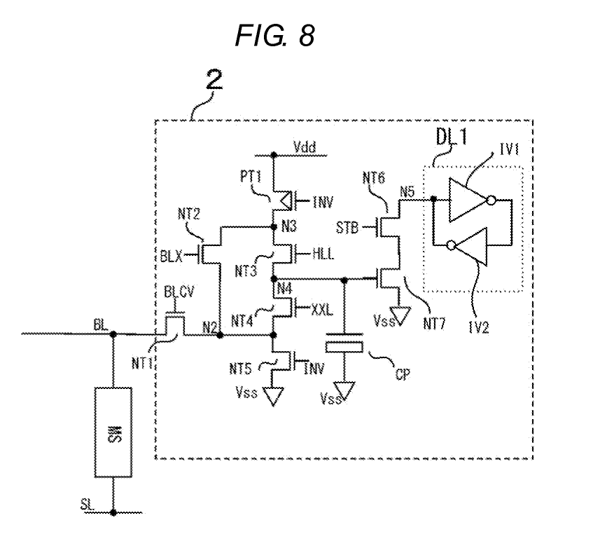

FIG. 5 is an equivalent circuit diagram of blocks. FIG. 6 is a circuit diagram illustrating a memory string. FIG. 7 is a block diagram illustrating a nonvolatile semiconductor memory device. FIG. 8 is a circuit diagram illustrating a sense amplifier and a bit line driver.

As illustrated in FIG. 5, the blocks BLK extend parallel to each other in the X direction and are arranged along the Y direction, in a plane parallel to the silicon substrate 11 and the semiconductor layer 12.

As illustrated in FIG. 6, the memory string MS includes the selection transistor STS, the memory cell MC, and the selection transistor STD. The selection transistor STS includes a gate connected to the selector gate line SGS. A memory cell transistor MCT0 includes a gate connected to the word line WL0. A memory cell transistor MCT1 includes a gate connected to the word line WL1. A memory cell transistor MCT2 includes a gate connected to the word line WL2. A memory cell transistor MCTm includes agate connected to the word line WLm. The selection transistor STD includes a gate connected to the selector gate line SGD.

As illustrated in FIG. 7, a nonvolatile semiconductor memory device 90 includes a memory cell array 1, a sense amplifier 2, a row decoder 3, and a voltage generation circuit 5. The nonvolatile semiconductor memory device 90 is a three-dimensional NAND flash memory.

A memory controller 100 and a host 200 receive and transmit data and signals therebetween. The nonvolatile semiconductor memory device 90 and the memory controller 100 receive and transmit data and signals therebetween. The memory controller 100 generates various commands for controlling an operation, addresses and data of the nonvolatile semiconductor memory device 90, and outputs the generated commands to the nonvolatile semiconductor memory device 90.

The sense amplifier 2 is connected to the bit lines BL0 to BLn to control voltage of the bit lines when reading, writing and erasing data. The sense amplifier 2 detects an electrical potential of the bit lines BL, for example, when reading the data stored in the memory cell transistor MCT.

The row decoder 3 is connected to the word lines WL0 to WLm to execute selection and driving of the word lines WL when reading, writing and erasing the data.

The control circuit 4 generates a control signal for controlling a sequence of data writing and data erasing and a control signal for controlling data reading based on an external control signal and a command supplied from the host 200 according to an operation mode. These control signals are transmitted to the row decoder 3, the sense amplifier 2, the voltage generation circuit 5, and the like.

The control circuit 4 performs, when data of the memory cell MC is read, a control for shielding a non-select bit line BL (setting the non-select bit line BL to a ground potential) and for sequentially reading the data of the memory cell MC connected to a select bit line BL in units of L adjacent bit lines BL.

The voltage generation circuit 6 generates a read voltage (Vread VCGR), a write voltage (VPGM), a verify voltage (VCGR_CV), and an erase voltage (VERA) according to various control signals transmitted from the control circuit 4. The voltage generation circuit 6 generates voltages necessary for respective operations of the memory cell array 1, the sense amplifier 2, and the row decoder 3.

As illustrated in FIG. 8, the sense amplifier 2 includes a capacitor CP, a data latch DL1, transistors NT1 to NT7, and a transistor PT1. The transistor PT1 (Pch transistor), the transistor NT3 (Nch transistor), the transistor NT4 (Nch transistor) and the transistor NT5 (Nch transistor) are connected in series between a high potential power source Vdd and the source line SL. All of the transistors NT1 to NT7 and the transistor PT1 are a MOSFET type.

Although the other end of the transistor NT5 is connected to a low potential power source (ground potential) Vss, it may be set to a cell source voltage CELSRC that is a voltage higher than the low potential power source (ground potential) Vss. In this case, the other end of the transistor NT5 is connected to the source line SL through a source line driver or the like, for example.

The transistor PT1 includes a gate connected to a control line INV. The transistor NT3 includes a gate connected to a control line HLL. The transistor NT4 includes agate connected to a control line XXL. The transistor NT5 includes a gate connected to the control line INV.

The transistor NT1 is connected to an end of the bit line BL at one end thereof, and is connected to a node N2 (a node between the transistor NT4 and the transistor NT5) at the other end thereof. Further, the transistor NT1 includes a gate connected to a control line BLCV. When the control line BLCV is at a “high” level, the transistor NT1 connects the bit line BL to the node N2.

The transistor NT2 (Nch transistor) is connected to a node N3 (node between the transistor PT1 and the transistor NT3) at one end thereof, and is connected to the node N2 at the other end thereof. Further, the transistor NT2 includes a gate connected to a control line BLX. When the control line BLX is at a “high” level, the transistor NT2 connects the node N2 to the node N3.

The capacitor CP is connected to a node N4 at one end thereof, and is connected to the low potential power source (ground potential) Vss at the other end thereof.

A transistor NT6 (Nch transistor) and a transistor NT7 (Nch transistor) are connected in series between a node N5 and the low potential power source (ground potential) Vss. The transistor NT6 includes agate connected to a control line STB. A transistor NT7 includes a gate connected to the node N4.

The data latch DL1 includes an inverter IV1 and an inverter IV2. The inverter IV1 is connected to the node N5 on an input side thereof, and is connected to the inverter IV2 on an output side thereof. The inverter IV2 is connected to the node N5 on an output side thereof. The data latch DL1 latches data of the node N5.

When the control line INV is at the “high” level, the non-select bit line BL is shielded (to the ground potential Vss) based on an instruction of the control circuit 4.

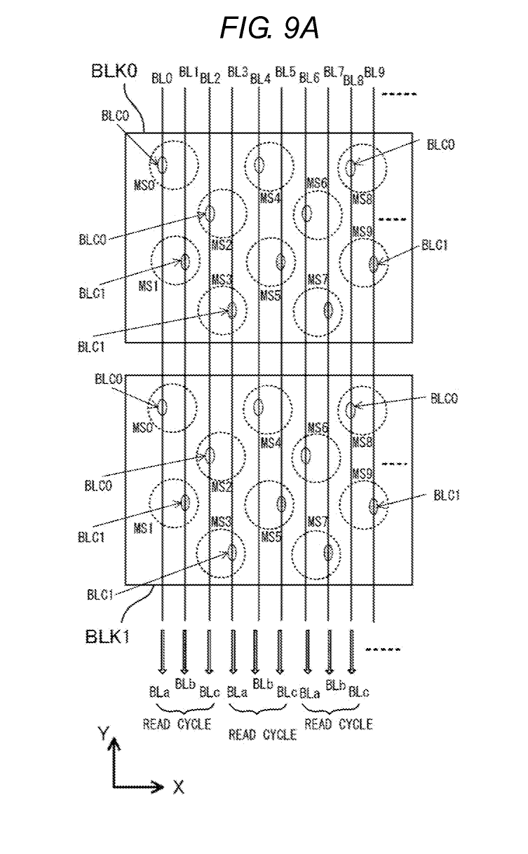

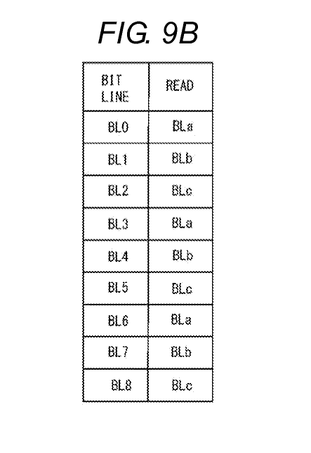

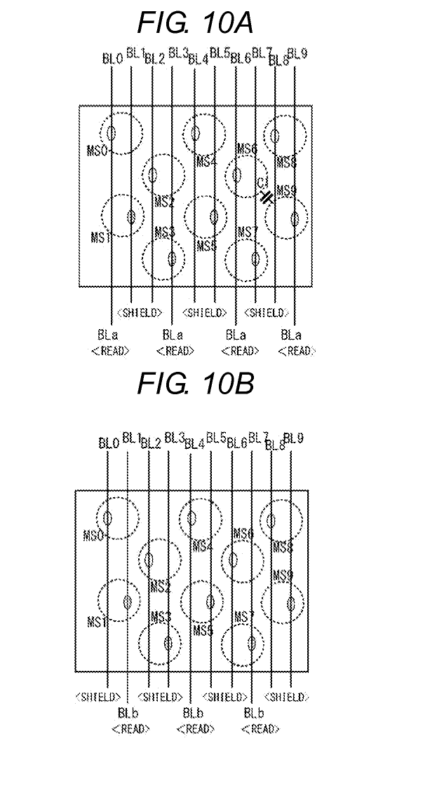

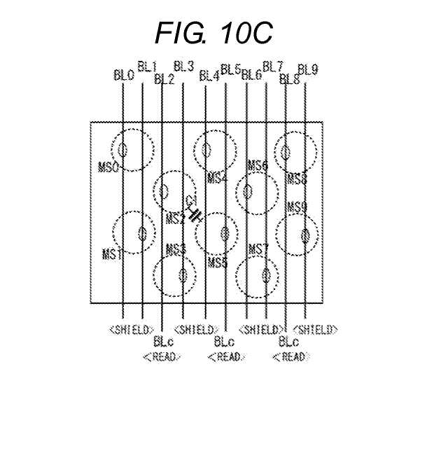

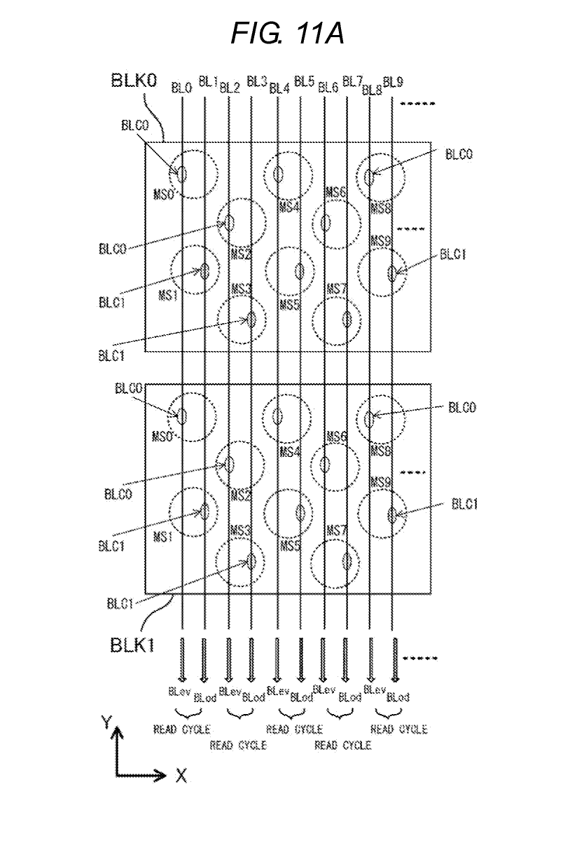

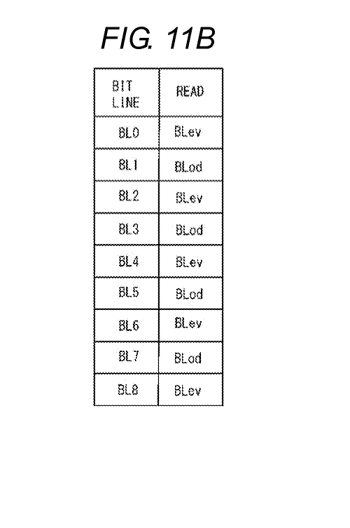

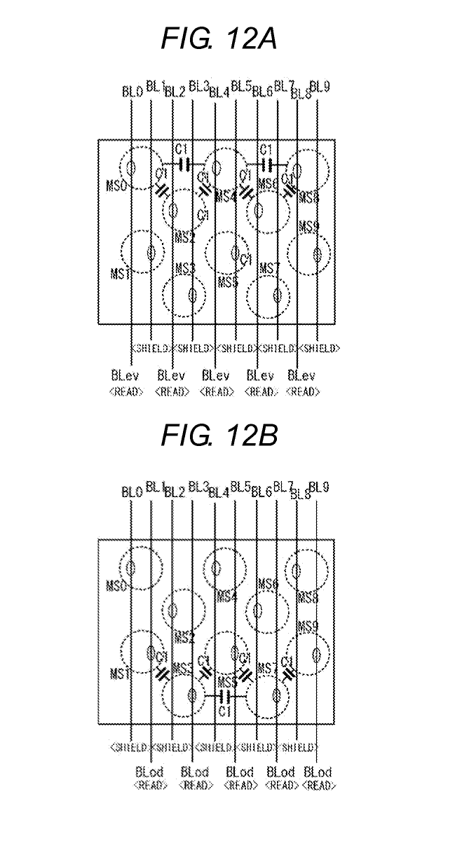

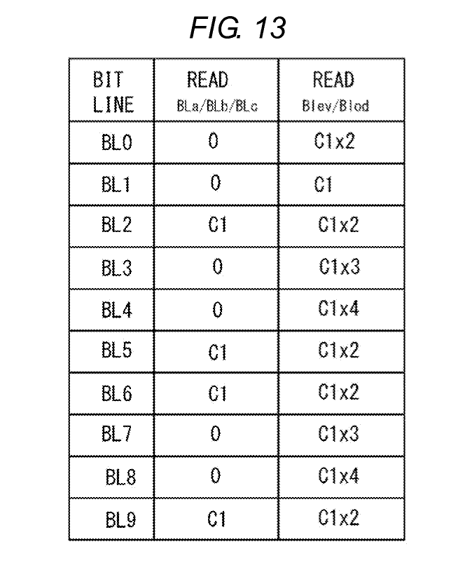

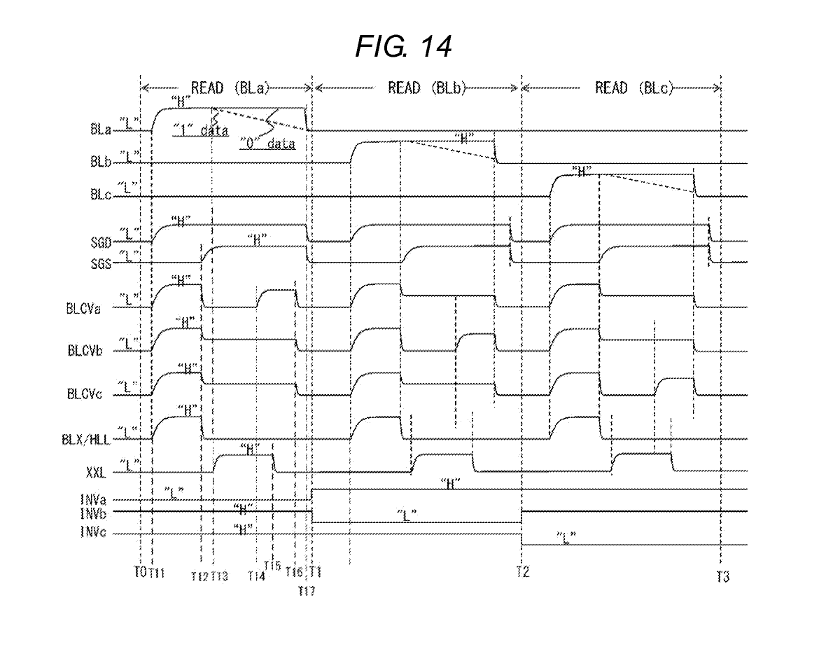

Next, a case where reading is performed in units of three bit lines that are adjacent in a four-line staggering pattern will be described with reference to FIGS. 9A to 14. FIGS. 9A and 9B are diagrams schematically illustrating a case where data is read in units of three bit lines that are adjacent in a four-line staggering pattern, according to the present embodiment. FIG. 10A is a diagram illustrating a bit line contact capacitance generated when a bit line BLa in the present embodiment is read, FIG. 10B is a diagram illustrating a bit line contact capacitance generated when a bit line BLb in the present embodiment is read, and FIG. 10C is a diagram illustrating a bit line contact capacitance generated when a bit line BLc in the present embodiment is read. FIGS. 11A and 11B are diagrams schematically illustrating a first comparative example in which data is read in units of two bit lines that are adjacent in a four-line staggering pattern. FIG. 12A is a diagram illustrating a bit line contact capacitance generated when a bit line BLev in the first comparative example is read, and FIG. 12B is a diagram illustrating a bit line contact capacitance generated when a bit line BLod in the first comparative example is read. FIG. 13 is a comparison diagram illustrating the bit line contact capacitances in the present embodiment and the bit line contact capacitances in the first comparative example. FIG. 14 is a timing chart illustrating a read operation of data of a memory cell connected to a bit line according to the first embodiment.

As illustrated in FIGS. 9A and 9B, the bit line BL0 (a first bit line) corresponds to the bit line BLa, the bit line BL1 (a second bit line) corresponds to the bit line BLb, and the bit line BL2 (a third bit line) corresponds to the bit line BLc, which are used as one reading unit, so that data of the memory cells MC is sequentially read. The bit line BL3 (a fourth bit line) corresponds to the bit line BLa, the bit line BL4 (a fifth bit line) corresponds to the bit line BLb, and the bit line BL5 (a sixth bit line) corresponds to the bit line BLc, which are used as one reading unit, so that data of the memory cells MC is sequentially read. The bit line BL6 (a seventh bit line) corresponds to the bit line BLa, the bit line BL7 (an eighth bit line) corresponds to the bit line BLb, and the bit line BL8 (a ninth bit line) corresponds to the bit line BLc, which are used as one reading unit, so that data of the memory cells MC is sequentially read.

As illustrated in FIG. 10A, in the present embodiment, when the bit line BLa is selected to read data of the memory cell MC and the bit lines BLb and BLc are not selected to be shielded, a bit line inter-contact capacitance C1 is generated between the memory string MS6 and the memory string MS9. In the other portions, since the surrounding memory strings MS are shielded, the capacitance C1 of the bit line inter-contact is not generated.

As illustrated in FIG. 10B, in the present embodiment, when the bit line BLb is selected to read data of the memory cell MC and the bit lines BLa and BLc are not selected to be shielded, since the surrounding memory strings MS are shielded, the capacitance C1 of the bit line inter-contact is not generated.

As illustrated in FIG. 10C, in the present embodiment, when the bit line BLc is selected to read data of the memory cell MC and the bit lines BLa and BLb are not selected to be shielded, a bit line inter-contact capacitance C1 is generated between the memory string MS2 and the memory string MS5. In the other portions, since the surrounding memory strings MS are shielded, the capacitance C1 of the bit line inter-contact is not generated.

As illustrated in FIGS. 11A and 11B, the bit line BL0 (a first bit line) corresponds to bit line BLev (an even-numbered bit line), and the bit line BL1 (a second bit line) corresponds to bit line BLod (an odd-numbered bit line), which are used as one reading unit, so that data of the memory cells MC is sequentially read. The bit line BL2 (a third bit line) corresponds to the bit line BLev, and the bit line BL3 (a fourth bit line) corresponds to the bit line BLod, which are used as one reading unit, so that data of the memory cells MC is sequentially read. The bit line BL4 (a fifth bit line) corresponds to the bit line BLev, and the bit line BL5 (a sixth bit line) corresponds to the bit line BLod, which are used as one reading unit, so that data of the memory cells MC is sequentially read. The bit line BL6 (a seventh bit line) corresponds to the bit line BLev, and the bit line BL7 (an eighth bit line) corresponds to the bit line BLod, which are used as one reading unit, so that data of the memory cells MC is sequentially read. The bit line BL8 (a ninth bit line) corresponds to the bit line BLev, and the bit line BL9 (a tenth bit line) corresponds to the bit line BLod, which are used as one reading unit, so that data of the memory cells MC is sequentially read.

As illustrated in FIG. 12A, in a first comparative example, when the bit line BLev (the even-numbered bit line) is selected to read data of the memory cell MC and the bit line BLod (the odd-numbered bit line) is shielded, the capacitance C1 of the bit line inter-contact is generated between the memory string MS0 and the memory string MS2, between the memory string MS0 and the memory string MS4, between the memory string MS2 and the memory string MS4, between the memory string MS4 and the memory string MS6, between the memory string MS4 and the memory string MS8, and between the memory string MS6 and the memory string MS8, respectively. In the other portions, since the surrounding memory strings MS are shielded, the capacitance C1 of the bit line inter-contact is not generated.

As illustrated in FIG. 12B, in the first comparative example, when the bit line BLod (the odd-numbered bit line) is selected to read data of the memory cell MC and the bit line BLev (the even-numbered bit line) is shielded, the capacitance C1 of the bit line inter-contact is generated between the memory string MS1 and the memory string MS3, between the memory string MS3 and the memory string MS5, between the memory string MS3 and the memory string MS7, between the memory string MS5 and the memory string MS7, and between the memory string MS7 and the memory string MS9, respectively. In the other portions, since the surrounding memory strings MS are shielded, the capacitance C1 of the bit line inter-contact is not generated.

As illustrated in FIG. 13, when the bit line BLa, the bit line BLb and the bit line BLc are used as one reading unit (case A1 of the present embodiment), compared with a case where the bit line BLev and the bit line BLod are used as one reading unit (case A2 of the first comparative example), it is possible to significantly reduce a capacitance of the bit line inter-contact. As a result, in the present embodiment, it is possible to significantly enhance the reliability of the read operation, compared with the first comparative example.

Specifically, in the case A1 of the present embodiment, the capacitance C1 of the bit line inter-contact is generated in the bit line BL2, the bit line BL5, the bit line BL6 and the bit line BL9, respectively.

On the other hand, in the case A2 of the first comparative example, the capacitance C1 of the bit line inter-contact is generated in the bit line BL1. Two times the capacitance C1 of the bit line inter-contact are generated in the bit line BL0, the bit line BL2, the bit line BL5, the bit line BL6 and the bit line BL9, respectively. Three times the capacitance C1 of the bit line inter-contact are generated in the bit line BL3 and the bit line BL7, respectively. Four time the capacitance C1 of the bit line inter-contact are generated in the bit line BL4 and the bit line BL8, respectively.

As illustrated in FIG. 14, first, the data of the memory cell MC connected to the bit line BLa between time T0 and time T1 is read. During this period of time, the bit line BLb and the bit line BLc are shielded.

Then, the data of the memory cell MC connected to the bit line BLb between time T1 and time T2 is read. During this period of time, the bit line BLa and the bit line BLc are shielded.

Subsequently, the data of the memory cell MC connected to the bit line BLc between time T2 and time T3 is read. During this period of time, the bit line BLa and the bit line BLb are shielded.

Here, a case where the data of the memory cell MC connected to the bit line BLa will be described as an example. Since a case where the data of the memory cell MC connected to the bit line BLb and a case where the data of the memory cell MC connected to the bit line BLc are the same as the above case, the description will not be repeated.

Between time T0 and time T1, a control line INVb (the control line INV in the sense amplifier 2 connected to the bit line BLb) and a control line INVc (the control line INV in the sense amplifier 2 connected to the bit line BLc) are set to a “high” level, the bit line BLb and the bit line BLc are shielded, and the node N2 of the sense amplifier 2 connected to the shielded bit lines BL is shielded. On the other hand, a control line INVa (the control line INV in the sense amplifier 2 connected to the bit line BLa) is set to a “low” level.

At time T11, a control line BLCVa (the control line BLCV in the sense amplifier 2 connected to the bit line BLa), the control line BLX of the sense amplifier 2 connected to the bit line BLa, the control line HLL of the sense amplifier 2 and the selector gate line SGD are changed from the “low” level to the “high” level. As a result, the bit line BLa for data reading is changed from the “low” level to the “high” level. At this time, the control line BLCVb in the shield bit line BLb and the control line BLCVc in the shield bit line BLc are also changed from the “low” level to the “high” level.

At time T12, the control lines BLCVa to BLCVc, the control line BLX and the control line HLL are changed from the “high” level to the “low” level. The selector gate line SGS is changed from the “low” level to the “high” level.

At time T13, the control line XXL is changed from the “low” level to the “high” level.

At time T14, the voltage level of the control line BLCVa is changed, and the voltage change of the bit line BL is transmitted to the node N4. When the data of the memory cell MC is “0” data, the bit line BLa maintains the “high” level. When the data of the memory cell is “1” data, the bit line BLa is changed from the “high” level to the “low” level. At time T15, the control line XXL is changed from the “high” level to the “low” level.

At time T16, the control lines BLCVa to BLCVc are changed to the “low” level, and the control line STB (not illustrated) is changed from the “low” level to the “high” level. As a result, the data of the memory cell is read by the sense amplifier 2. At this point of time, the read operation of the data of the memory cell connected to the bit line BLa by the sense amplifier 2 is terminated.

At time T17, the selector gate line SGD and the selector gate line SGS are changed from the “high” level to the “low” level. Further, the bit line BLa is changed to the “low” level.

As described above, in the nonvolatile semiconductor memory device according to the present embodiment, the blocks BLK0 to BLKs that extend parallel to each other in the X direction and are arranged along the Y direction are provided in the memory cell array 1. The blocks BLK0 to BLKs are respectively connected to the selector gate line SGS0, the word lines WL0 to WLm and the selector gate line SGD0 on one end sides thereof in the X direction, and are connected to the bit lines BL0 to BLn in the Y direction. The plurality of memory strings MS are arranged in a four-line staggering pattern in each of the blocks BLK0 to BLKs. The bit lines BL0 to BLn are sequentially connected to the plurality of memory strings MS through the bit line contact BLC0 or the bit line contact BLC1. When reading the data of the memory cell MC, the control circuit 4 performs the control for sequentially reading the data of the memory cell MC connected to the selected bit line in units of three adjacent bit lines BL, with the unselected bit lines being shielded. The sense amplifier 2 reads the data of the memory cell MC based on the instruction of the control circuit 4.

Thus, compared with a case where the data of the memory cell MC connected to the selected bit line in units of adjacent even-numbered bit lines and odd-numbered bit lines with the unselected bit lines being shielded, it is possible to significantly reduce a capacitance of the bit line inter-contact. Accordingly, it is possible to significantly enhance of the reliability of the read operation of the data of the memory cell MC by the nonvolatile semiconductor memory device 90.

In the present embodiment, the reading of the data of the memory cells MC is performed based on the instruction of the control circuit 4, but instead, may be performed based on an instruction of the memory controller 100. The present embodiment is applied to the nonvolatile semiconductor memory device 90 having the memory string MS in which the bit line BL is disposed on the upper side in the Z direction and the source line SL is disposed on the lower side in the Z direction, but instead, may be applied to a nonvolatile semiconductor memory device having a U-shaped memory string in which the bit line BL is arranged on the highest side in the Z direction and the source line SL is arranged on the upper side in the Z direction.

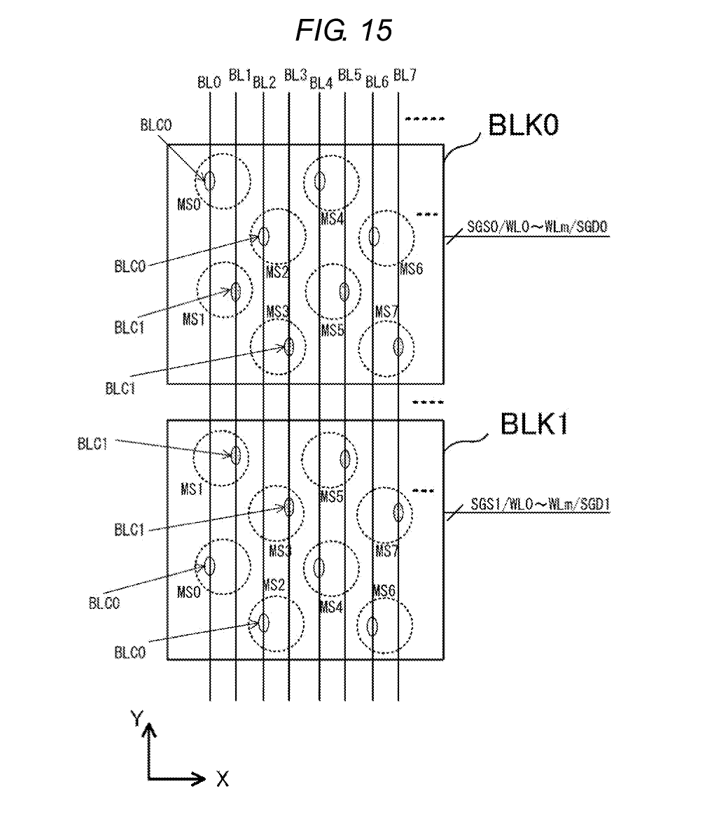

Further, as in a first modification example illustrated in FIG. 15, the arrangement of the bit line contacts BLC0 and BLC1 may be changed in adjacent two blocks. Specifically, as illustrated in FIG. 15, in the blocks BLK0 and BLK1, the plurality of memory strings MS have the same shape, and are arranged in a four-line staggering pattern.

In the block BLK0, the bit line BL0 (the first bit line) is connected to the memory string MS0 that is a first memory string when seen from one side in the Y direction, through the bit line contact BLC0. The bit line BL1 (the second bit line) is connected to the memory string MS1 that is a third memory string when seen from one side in the Y direction, through the bit line contact BLC1. The bit line BL2 (the third bit line) is connected to the memory string MS2 that is a second memory string when seen from one side in the Y direction, through the bit line contact BLC0. The bit line BL3 (the fourth bit line) is connected to the memory string MS3 that is a fourth memory string when seen from one side in the Y direction, through the bit line contact BLC1.

On the other hand, the bit line BL0 (the first bit line) is connected to the memory string MS0 that is a third memory string when seen from one side in the Y direction, through the bit line contact BLC0. The bit line BL1 (the second bit line) is connected to the memory string MS1 that is a first memory string when seen from one side in the Y direction, through the bit line contact BLC1. The bit line BL2 (the third bit line) is connected to the memory string MS2 that is a fourth memory string when seen from one side in the Y direction, through the bit line contact BLC0. The bit line BL3 (the fourth bit line) is connected to the memory string MS3 that is a second memory string when seen from one side in the Y direction, through the bit line contact BLC1.

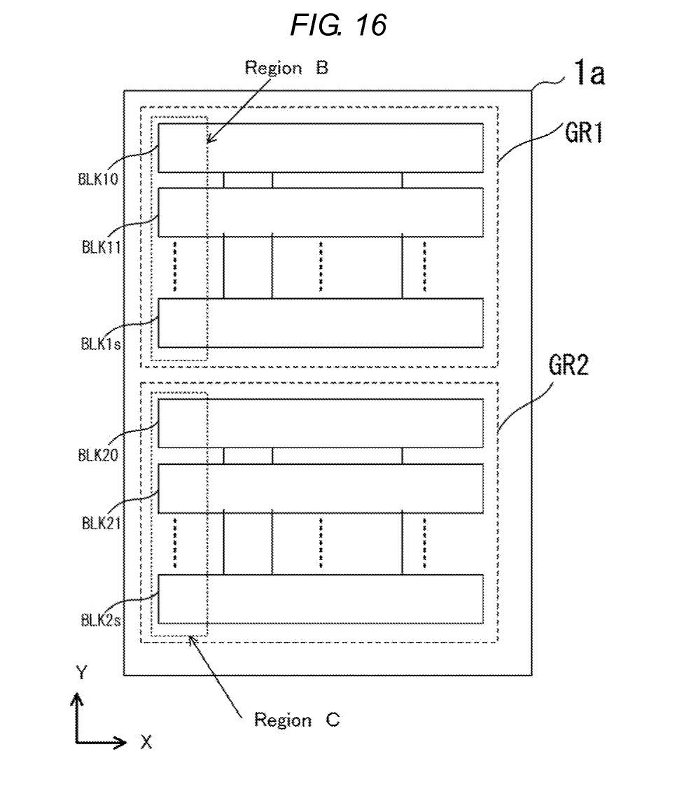

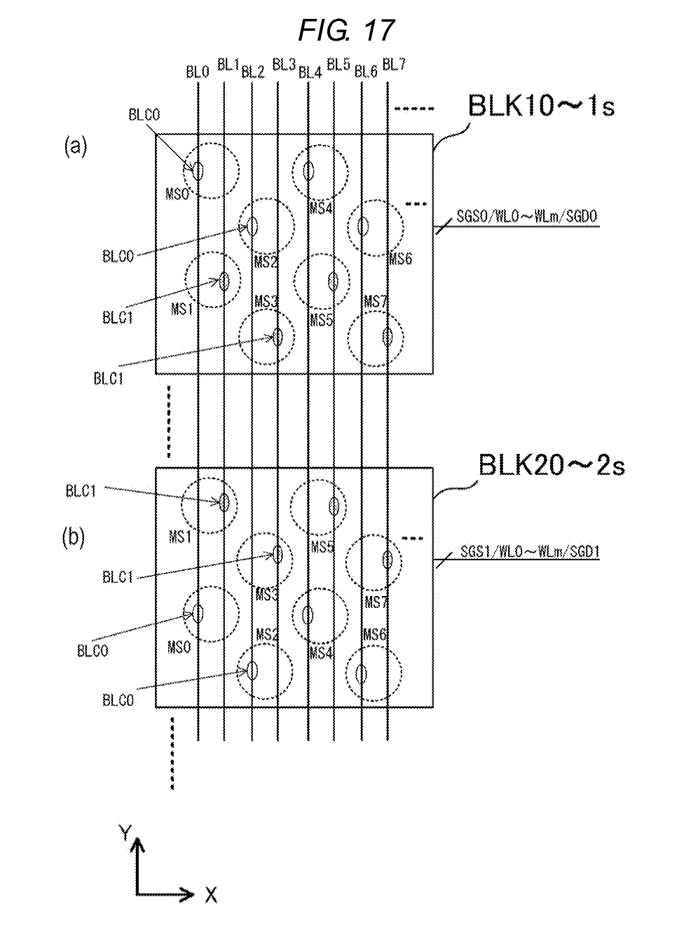

Further, as in a second modification example illustrated in FIGS. 16 and 17, the arrangement of the bit line contacts BLC0 and BLC1 may be changed in two adjacent block groups. Specifically, as illustrated in FIG. 16, a memory cell array 1a includes block groups GR1 and GR2. The block group GR1 includes blocks BLK10 to BLK1s that extend parallel to each other in the X direction and are arranged along the Y direction. The block group GR2 includes blocks BLK20 to BLK2s that extend parallel to each other in the X direction and are arranged along the Y direction.

As illustrated in FIG. 17, the blocks BLK10 to BLK1s have the same arrangement as that of the block BLK0 of the first modification example illustrated in FIG. 15, respectively. The blocks BLK20 to BLK2s have the same arrangement as that of the block BLK1 of the first modification example illustrated in FIG. 15, respectively.

According to the first modification example and the second modification example, it is possible to significantly reduce a capacitance of the bit line inter-contact compared with the first comparative example, similar to the first embodiment. Accordingly, it is possible to significantly enhance the reliability of the read operation of the data of the memory cell MC in the nonvolatile memory device.

### Second Embodiment

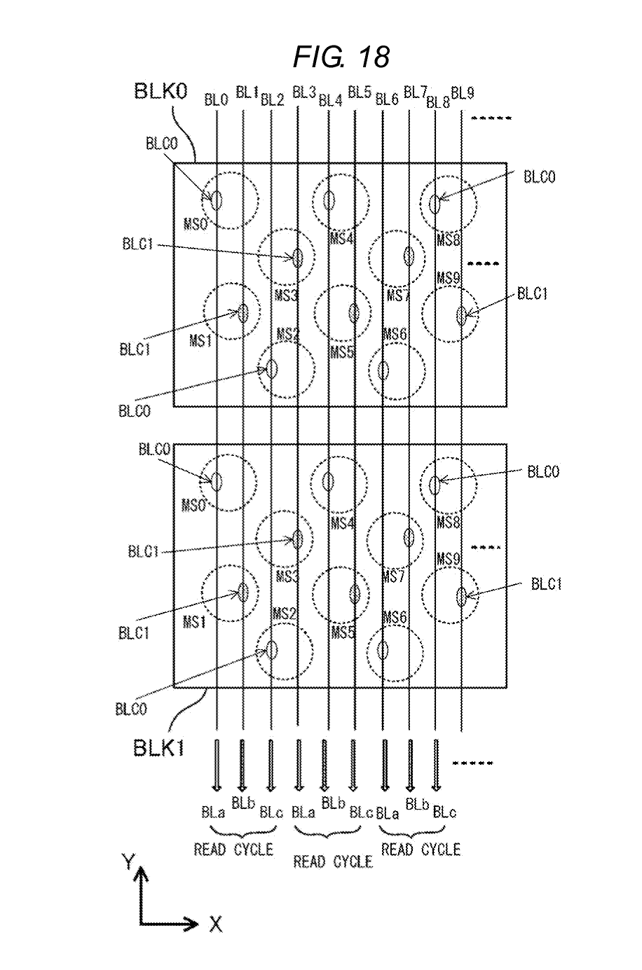

Next, a nonvolatile semiconductor memory device according to a second embodiment will be described with reference to the accompanying drawings. FIG. 18 is a diagram schematically illustrating a case where data is read in units of three bit lines that are adjacent in a four-line staggering pattern. In the present embodiment, the arrangement of the bit line contacts is changed with respect to the first embodiment.

As illustrated in FIG. 18, similar to the first embodiment, for example, in the block BLK0 and the block BLK1, a plurality of memory strings MS are arranged in a four-line staggering pattern. The plurality of memory strings MS have the same shape, and are connected to the bit lines BL through the bit line contact BLC0 or the bit line contact BLC1. The bit line contact BLC0 is provided on one side in the X direction (the first direction). The bit line contact BLC1 is provided on the other side in the X direction (the first direction). Data is read in units of three adjacent bit lines.

Specifically, the bit line BL0 (the first bit line) is connected to the memory string MS0 that is a first memory string when seen from one side in the Y direction, through the bit line contact BLC0. The bit line BL1 (the second bit line) is connected to the memory string MS1 that is a third memory string when seen from one side in the Y direction, through the bit line contact BLC1. The bit line BL2 (the third bit line) is connected to the memory string MS2 that is a fourth memory string when seen from one side in the Y direction, through the bit line contact BLC0. The bit line BL3 (the fourth bit line) is connected to the memory string MS3 that is a second memory string when seen from one side in the Y direction (the second direction), through the bit line contact BLC1. The bit line BL4 (the fifth bit line) and thereafter repeat the same arrangement shape, and thus, the description is not repeated.

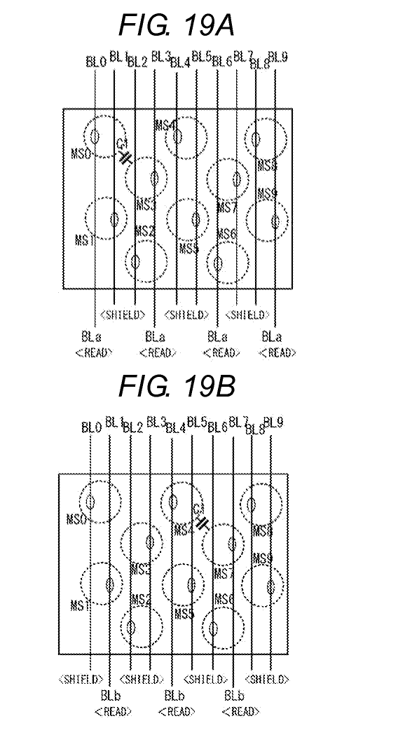

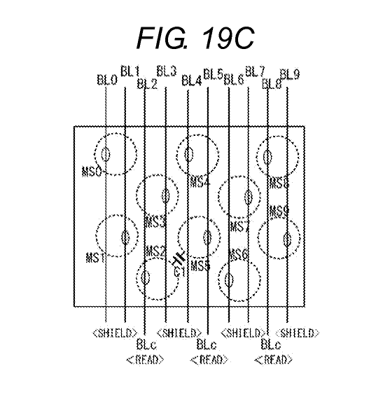

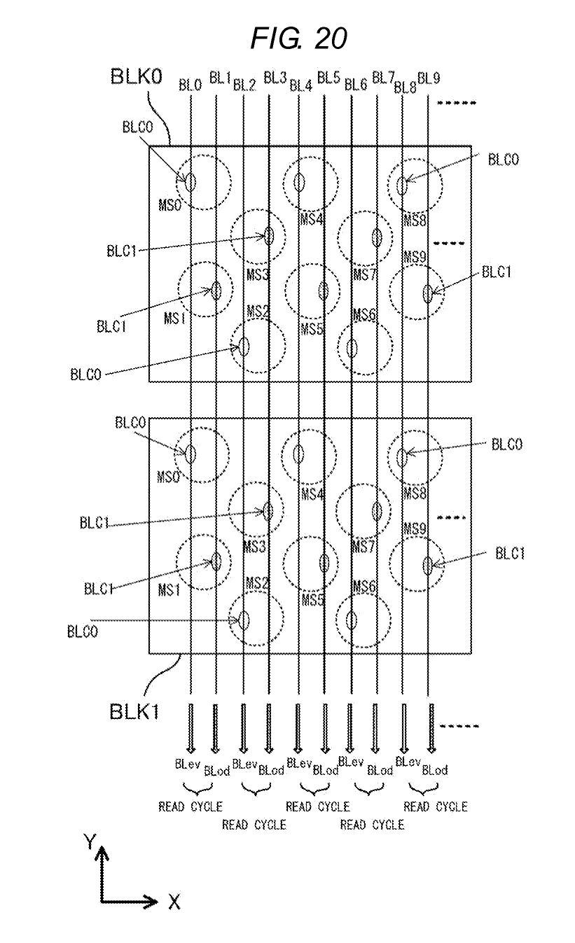

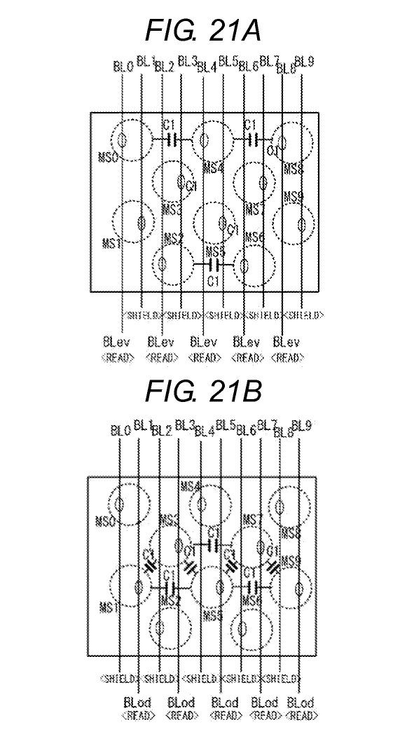

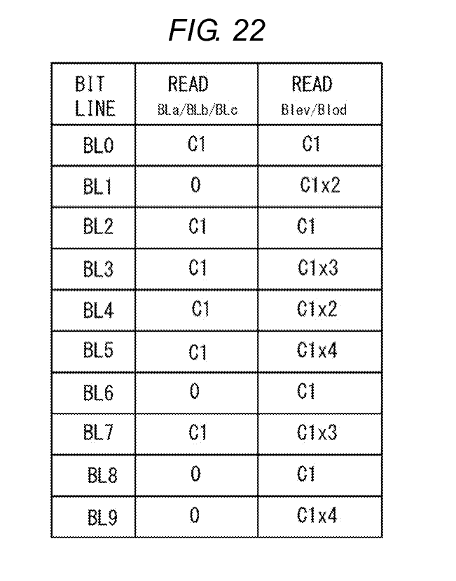

Next, a case where data is read in units of three bit lines that are adjacent in a four-line staggering pattern will be described with reference to FIGS. 19A to 22. FIG. 19A is a diagram illustrating a bit line contact capacitance generated when a bit line BLa in the present embodiment is read, FIG. 19B is a diagram illustrating a bit line contact capacitance generated when a bit line BLb in the present embodiment is read, and FIG. 19C is a diagram illustrating a bit line contact capacitance generated when a bit line BLc in the present embodiment is read. FIG. 20 is a diagram schematically illustrating a second comparative example in which data is read in units of two bit lines that are adjacent in a four staggering pattern. FIG. 21A is a diagram illustrating a bit line contact capacitance generated when a bit line BLev in the second comparative example is read, and FIG. 21B is a diagram illustrating a bit line contact capacitance generated when a bit line BLod in the second comparative example is read. FIG. 22 is a comparison diagram illustrating the bit line contact capacitances in the present embodiment and the bit line contact capacitances in the second comparative example.

As illustrated in FIG. 19A, in the present embodiment, when the bit line BLa is selected to read the data of the memory cell MC and the bit lines BLb and BLc are not selected to be shielded, the capacitance C1 of the bit line inter-contact is generated between the memory string MS0 and the memory string MS3. In the other portions, since the surrounding memory strings MS are shielded, the capacitance C1 of the bit line inter-contact is not generated.

As illustrated in FIG. 19B, in the present embodiment, when the bit line BLb is selected to read the data of the memory cell MC and the bit lines BLa and BLc are not selected to be shielded, the capacitance C1 of the bit line inter-contact is generated between the memory string MS4 and the memory string MS7. In the other portions, since the surrounding memory strings MS are shielded, the capacitance C1 of the bit line inter-contact is not generated.

As illustrated in FIG. 19C, in the present embodiment, when the bit line BLc is selected to read the data of the memory cell MC and the bit lines BLa and BLb are not selected to be shielded, the capacitance C1 of the bit line inter-contact is generated between the memory string MS2 and the memory string MS5. In the other portions, since the surrounding memory strings MS are shielded, the capacitance C1 of the bit line inter-contact is not generated.

As illustrated in FIG. 20, in a second comparative example, similar to the first modification example illustrated in the first embodiment, the bit line BLev (an even-numbered bit line) and the bit line BLod (an odd-numbered bit line) that are adjacent are used as one reading unit, and the data of the memory cells MC is sequentially read. In the second comparative example, the arrangement of the bit line contacts BLC0 and BLC1 is the same as in the present embodiment (see FIG. 18).

As illustrated in FIG. 21A, in the second comparative example, when the bit line BLev (an even-numbered bit line) is selected to read the data of memory cell MC and the bit line BLod (an odd-numbered bit line) is shielded, the capacitance C1 of the bit line inter-contact is generated between the memory string MS0 and the memory string MS4, between the memory string MS2 and the memory string MS6, and between the memory string MS4 and the memory string MS8, respectively. Further, since the surrounding memory strings MS are shielded, the capacitance C1 of the bit line inter-contact is not generated.

As illustrated in FIG. 21B, in the second comparative example, when the bit line BLod (the odd-numbered bit line) is selected to read the data of memory cell MC and the bit line BLev (the even-numbered bit line) is shielded, the capacitance C1 of the bit line inter-contact is generated between the memory string MS1 and the memory string MS3, between the memory string MS1 and the memory string MS5, between the memory string MS3 and the memory string MS5, between the memory string MS3 and the memory string MS7, between the memory string MS5 and the memory string MS7, between the memory string MS5 and the memory string MS9, and between the memory string MS7 and the memory string MS9, respectively. Further, since the surrounding memory strings MS are shielded, the capacitance C1 of the bit line inter-contact is not generated.

As illustrated in FIG. 22, when the bit line BLCa, the bit line BLCb and the bit line BLCc are used as one reading unit (case B1 of the present embodiment), compared with a case where the bit line BLev and the bit line BLod are used as one read unit (case B2 of the second comparative example), it is possible to significantly reduce a capacitance of the bit line inter-contact. As a result, in the present embodiment, it is possible to significantly enhance the reliability of the read operation, compared with the second comparative example.

Specifically, in the case B1 of the present embodiment, the capacitance C1 of the bit line inter-contact is generated in the bit line BL0, the bit lines BL2 to BL5 and the bit line BL7, respectively.

On the other hand, in the case B2 of the second comparative example, the capacitance C1 of the bit line inter-contact is generated in the bit line BL0, the bit line BL2, the bit line BL6 and the bit line BL8, respectively. Two times the capacitance C1 of the bit line inter-contact are generated in the bit line BL1 and the bit line BL4, respectively. Three times the capacitance C1 of the bit line inter-contact are generated in the bit line BL3 and the bit line BL7, respectively. Four times the capacitance C1 of the bit line inter-contact are generated in the bit line BL5 and the bit line BL9, respectively.

As described above, in the nonvolatile semiconductor memory device of the present embodiment, the plurality of memory string MS are arranged in a four-line staggering pattern in each of the blocks BLK0 to BLKs. The bit lines BL0 to BLn are sequentially connected to the plurality of memory strings MS through the bit line contact BLC0 or the bit line contact BLC1. The arrangement of the bit line contact BLC0 or the bit line contact BLC1 is different from that of the first embodiment. Thus, the second embodiment has the same effect as that of the first embodiment.

### Third Embodiment

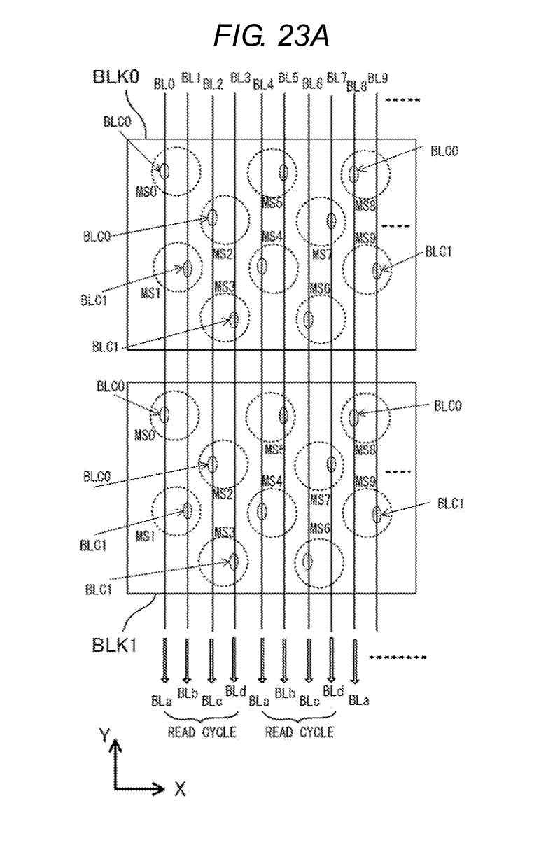

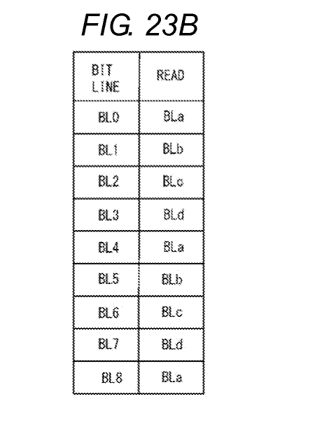

Then, a nonvolatile semiconductor memory device according to a third embodiment will be described with reference to the accompanying drawings. FIGS. 23A and 23B are diagrams schematically illustrating a case where data is read in units of four bit lines that are adjacent in a four-line staggering pattern. In the present embodiment, the data of the memory cells connected to the bit lines are sequentially read in units of four adjacent bit lines.

As illustrated in FIGS. 23A and 23B, the data of the memory cell connected to the bit lines BL is read in units of four adjacent bit lines (BLa to BLd). For example, in the block BLK0 and the block BLK1, a plurality of memory strings MS are arranged in a four-line staggering pattern. The plurality of memory strings MS have the same shape, and are connected to the bit lines BL through the bit line contact BLC0 or the bit line contact BLC1. The bit line contact BLC0 or the bit line contact BLC1 are repeatedly arranged in units of eight adjacent memory strings when seen in the X direction. The data is read in units of adjacent four bit lines (BLa to BLd).

Specifically, the bit line BL0 (the first bit line) is connected to the memory string MS0 that is a first memory string when seen from one side in the Y direction, through the bit line contact BLC0. The bit line BL1 (the second bit line) is connected to the memory string MS1 that is a third memory string when seen from one side in the Y direction, through the bit line contact BLC1. The bit line BL2 (the third bit line) is connected to the memory string MS2 that is a second memory string when seen from one side in the Y direction, through the bit line contact BLC0. The bit line BL3 (the fourth bit line) is connected to the memory string MS3 that is a fourth memory string when seen from one side in the Y direction (the second direction), through the bit line contact BLC1. The bit line BL4 (the fifth bit line) is connected to the memory string MS4 that is a third memory string when seen from one side in the Y direction, through the bit line contact BLC0. The bit line BL5 (the sixth bit line) is connected to the memory string MS5 that is a first memory string when seen from one side in the Y direction, through the bit line contact BLC1. The bit line BL6 (the seventh bit line) is connected to the memory string MS6 that is a fourth memory string when seen from one side in the Y direction, through the bit line contact BLC0. The bit line BL7 (the eighth bit line) is connected to the memory string MS7 that is a second memory string when seen from one side in the Y direction (the second direction), through the bit line contact BLC1. Since the bit line BL8 (the ninth bit line) and thereafter repeats the same arrangement shape, the description will not be repeated.

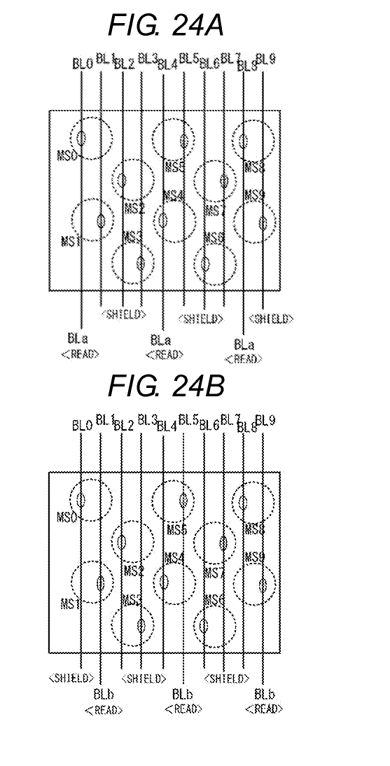

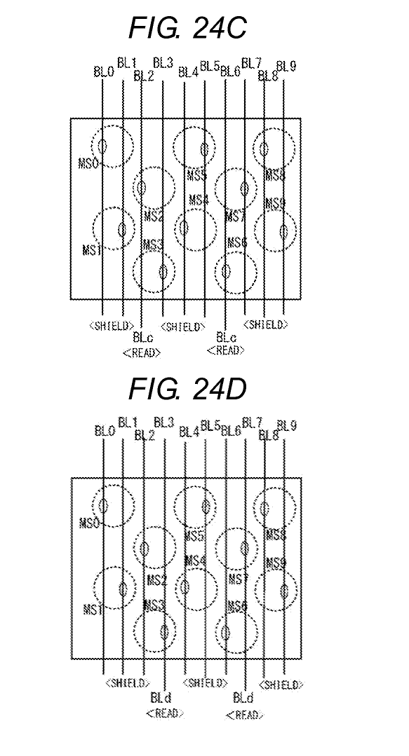

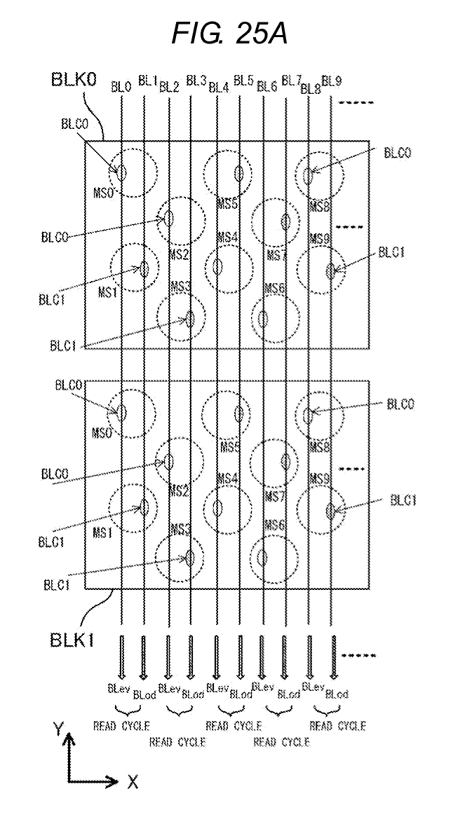

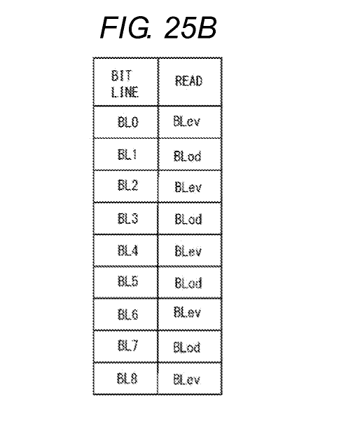

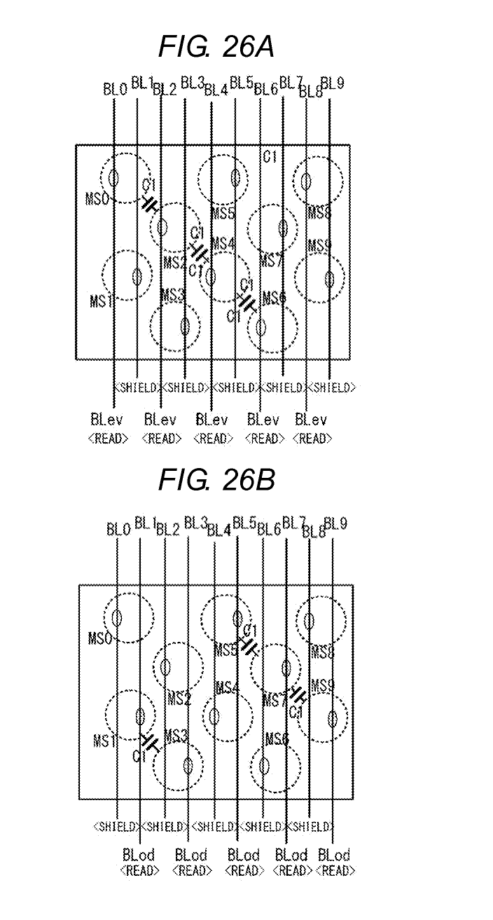

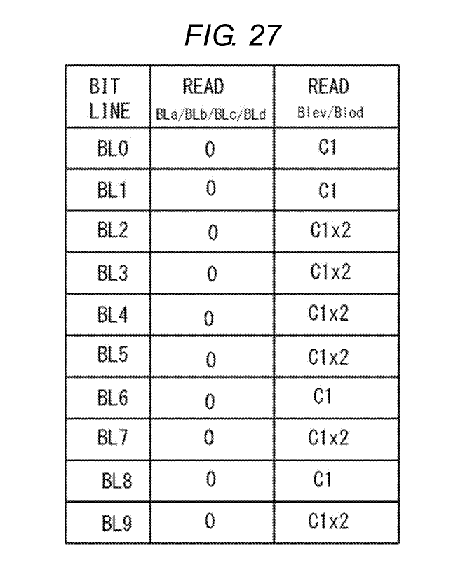

Next, a case where reading is performed in units of four bit lines that are adjacent in a four-line staggering pattern will be described with reference to FIG. 24A to FIG. 27. FIG. 24A is a diagram illustrating a bit line contact capacitance generated when a bit line BLa in the present embodiment is read, FIG. 24B is a diagram illustrating a bit line contact capacitance generated when a bit line BLb in the present embodiment is read, FIG. 24C is a diagram illustrating a bit line contact capacitance generated when a bit line BLc in the present embodiment is read, and FIG. 24D is a diagram illustrating a bit line contact capacitance generated when a bit line BLd in the present embodiment is read. FIGS. 25A and 25B are diagrams schematically illustrating a third comparative example in which data is read in units of two bit lines that are adjacent in a four-line staggering pattern. FIG. 26A is a diagram illustrating a bit line contact capacitance generated when a bit line BLev in the third comparative example is read, and FIG. 26B is a diagram illustrating a bit line contact capacitance generated when a bit line BLod in the third comparative example is read. FIG. 27 is a comparison diagram illustrating the bit line contact capacitances in the present embodiment and the bit line contact capacitances in the third comparative example.

As illustrated in FIG. 24A, in the present embodiment, when the bit line BLa is selected to read the data of the memory cell MC and the bit lines BLb to BLd are not selected to be shielded, since the surrounding memory strings MS are shielded, the capacitance C1 of the bit line inter-contact is not generated.

As illustrated in FIG. 24B, in the present embodiment, when the bit line BLb is selected to read the data of the memory cell MC and the bit lines BLa, BLc and BLd are not selected to be shielded, since the surrounding memory strings MS are shielded, the capacitance C1 of the bit line inter-contact is not generated.

As illustrated in FIG. 24C, in the present embodiment, when the bit line BLc is selected to read the data of the memory cell MC and the bit lines BLa, BLb and BLd are not selected to be shielded, since the surrounding memory strings MS are shielded, the capacitance C1 of the bit line inter-contact is not generated.

As illustrated in FIG. 24D, in the present embodiment, when the bit line BLd is selected to read the data of the memory cell MC and the bit lines BLa to BLc are not selected to be shielded, since the surrounding memory strings MS are shielded, the capacitance C1 of the bit line inter-contact is not generated.

As illustrated in FIGS. 25A and 25B, in a third comparative example, the bit line contacts BLC0 and BLC1 have the same arrangement as that of the present embodiment (see FIGS. 23A and 23B).

As illustrated in FIG. 26A, in the third comparative example, when the bit line BLev (an even-numbered bit line) is selected to read the data of the memory cell MC and the bit line BLod (an odd-numbered bit line) is shielded, the capacitance C1 of the bit line inter-contact is generated between the memory string MS0 and the memory string MS2, between the memory string MS2 and the memory string MS4, and between the memory string MS4 and the memory string MS6, respectively. In the other portions, since the surrounding memory strings MS are shielded, the capacitance C1 of the bit line inter-contact is not generated.

As illustrated in FIG. 26B, in the third comparative example, when the bit line BLod (the odd-numbered bit line) is selected to read the data of the memory cell MC and the bit line BLev (the even-numbered bit line) is shielded, the capacitance C1 of the bit line inter-contact is generated between the memory string MS1 and the memory string MS3, between the memory string MS5 and the memory string MS5, and between the memory string MS7 and the memory string MS9, respectively. In the other portions, since the surrounding memory strings MS are shielded, the capacitance C1 of the bit line inter-contact is not generated.

As illustrated in FIG. 27, when the bit lines BLCa to BLCd are used as one reading unit (case C1 of the present embodiment), compared with a case where the bit line BLev and the bit line BLod are used as one read unit (case C2 of the third comparative example), it is possible to significantly reduce a capacitance of the bit line inter-contact. As a result, in the present embodiment, it is possible to significantly enhance the reliability of the read operation of the data of the memory cell MC, compared with the third comparative example.

Specifically, in the case C1 of the present embodiment, a capacitance C1 of the bit line inter-contact is not generated.

On the other hand, in the case C2 of the third comparative example, the capacitance C1 of the bit line inter-contact is generated in the bit line BL0, the bit line BL2, the bit line BL6 and the bit line BL8, respectively. Two times as large as the capacitance C1 of the bit line inter-contact is generated in the bit lines BL2 to BL5, and the bit line BL7, respectively.

As described above, in the nonvolatile semiconductor memory device according to the present embodiment, the plurality of memory strings MS are arranged in a four-line staggering pattern in each of the blocks BLK0 to BLKs. In units of eight adjacent bit lines BL, the plurality of memory strings MS are connected to the bit line contact BLC0 or the bit line contact BLC1. In units of four adjacent bit lines, the data of the memory cells connected to the bit line is sequentially read.

In the nonvolatile semiconductor memory device according to the present embodiment, since the surrounding memory strings MS are shielded, the capacitance C1 of the bit line inter-contact is not generated. Accordingly, it is possible to significantly enhance the reliability of the read operation of the data of the memory cell MC, compared with the nonvolatile semiconductor memory device 90 according to the first embodiment.

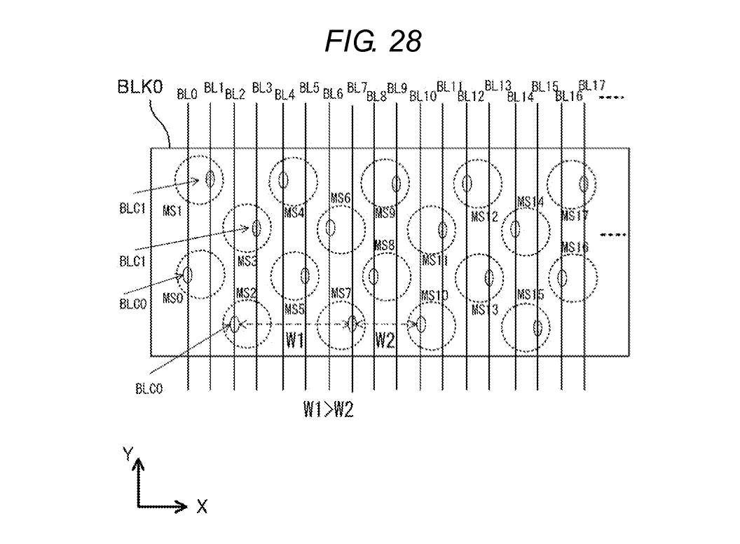

As in a third modification example illustrated in FIG. 28, the memory strings MS may be connected to the bit line contact BLC0 or the bit line contact BLC1 in units of adjacent eight bit lines BL. Here, the arrangement is changed compared with the third embodiment.

Specifically, the bit line BL0 (the first bit line) is connected to the memory string MS0 that is a third memory string when seen from one side in the Y direction, through the bit line contact BLC0. The bit line BL1 (the second bit line) is connected to the memory string MS1 that is a first memory string when seen from one side in the Y direction, through the bit line contact BLC1. The bit line BL2 (the third bit line) is connected to the memory string MS2 that is a fourth memory string when seen from one side in the Y direction, through the bit line contact BLC0. The bit line BL3 (the fourth bit line) is connected to the memory string MS3 that is a second memory string when seen from one side in the Y direction (the second direction), through the bit line contact BLC1. The bit line BL4 (the fifth bit line) is connected to the memory string MS4 that is a first memory string when seen from one side in the Y direction, through the bit line contact BLC0. The bit line BL5 (the sixth bit line) is connected to the memory string MS5 that is a third memory string when seen from one side in the Y direction, through the bit line contact BLC1. The bit line BL6 (the seventh bit line) is connected to the memory string MS6 that is a second memory string when seen from one side in the Y direction, through the bit line contact BLC0. The bit line BL7 (the eighth bit line) is connected to the memory string MS7 that is a fourth memory string when seen from one side in the Y direction (the second direction), through the bit line contact BLC1. Since the bit line BL8 (the ninth bit line) and thereafter repeat the same arrangement shape, the description will not be repeated.

In the third modification example and the third embodiment, a bit line contact interval W1 in the Y direction is larger than a bit line contact interval W2 in the Y direction.

According to the third modification example, it is possible to significantly reduce a capacitance of the bit line inter-contact, similar to the embodiment. Accordingly, it is possible to significantly enhance the reliability of the read operation of the data of the memory cell MC in the nonvolatile semiconductor memory.

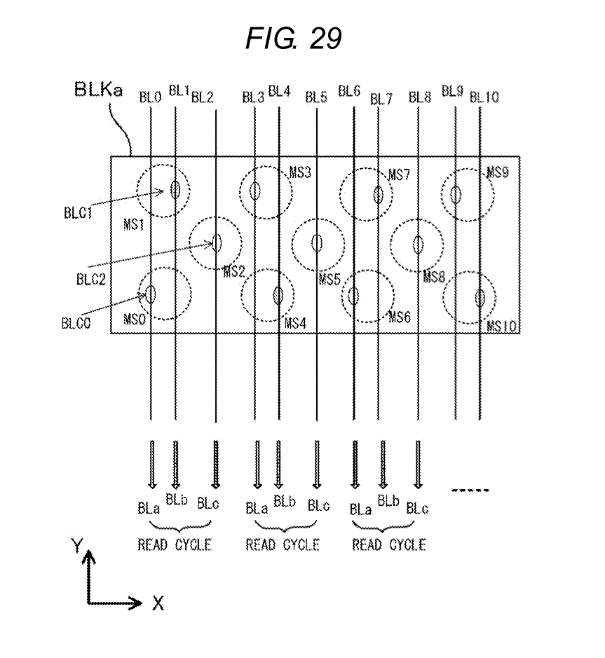

Further, as in a fourth modification example illustrated in FIG. 29, the plurality of memory strings MS may be arranged in a three-line staggering pattern, and the data of the memory cells connected to the bit lines may be sequentially read in units of three adjacent bit lines BL.

The plurality of memory strings MS are provided in a block BLKa. The plurality of memory strings MS have the same shape, and are connected to the bit lines BL through the bit line contact BLC0, the bit line contact BLC1 or a bit line contact BLC2. The bit line contact BLC0 is provided on one side in the X direction (the first direction). The bit line contact BLC1 is provided on the other side in the X direction (the first direction). The bit line contact BLC2 is provided at a central portion thereof.

Specifically, the bit line BL0 (the first bit line) is connected to the memory string MS0 that is a third memory string when seen from one side in the Y direction, through the bit line contact BLC0. The bit line BL1 (the second bit line) is connected to the memory string MS1 that is a first memory string when seen from one side in the Y direction, through the bit line contact BLC1. The bit line BL2 (the third bit line) is connected to the memory string MS2 that is a second memory string when seen from one side in the Y direction, through the bit line contact BLC2. Since the bit line BL3 (the fourth bit line) and thereafter repeat the same arrangement shape, the description will not be repeated.

According to the fourth modification example, it is possible to significantly reduce a capacitance of the bit line inter-contact, similar to the embodiment. Accordingly, it is possible to significantly enhance the reliability of the read operation of the data of the memory cell MC in the nonvolatile semiconductor memory device.

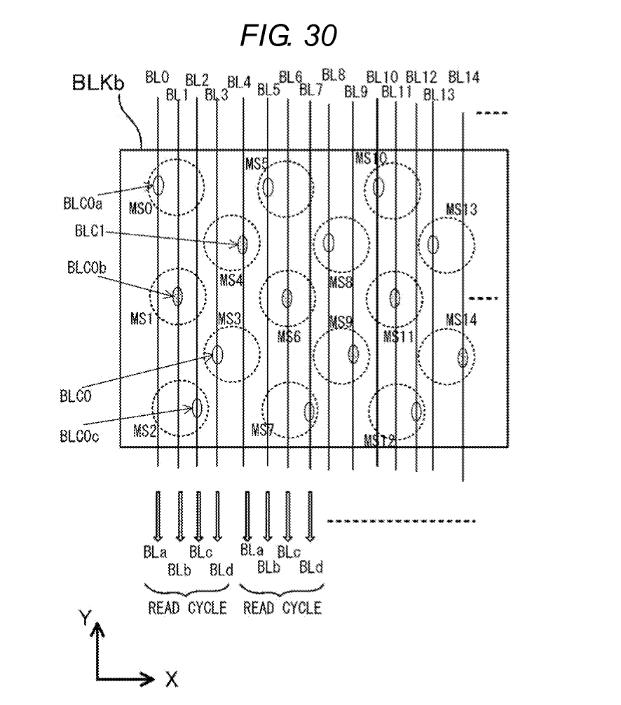

Further, as in a fifth modification example illustrated in FIG. 30, the plurality of memory strings MS may be arranged in a five-line staggering pattern, and the data of the memory cells connected to the bit lines may be sequentially read in units of four adjacent bit lines BL.

The plurality of memory strings MS are provided in a block BLKb. The plurality of memory strings MS have the same shape, and are connected to the bit lines BL through the bit line contact BLC0, the bit line contact BLC1, a bit line contact BLC0a, a bit line contact BLC0b or a bit line contact BLC0c. The bit line contact BLC0a is provided on one side in the X direction (the first direction). The bit line contact BLC0b is provided at a central portion thereof. The bit line contact BLC0c is provided on the other side in the X direction (the first direction).

Specifically, the bit line BL0 (the first bit line) is connected to the memory string MS0 that is a first memory string when seen from one side in the Y direction, through the bit line contact BLC0a. The bit line BL1 (the second bit line) is connected to the memory string MS1 that is a third memory string when seen from one side in the Y direction, through the bit line contact BLC0b. The bit line BL2 (the third bit line) is connected to the memory string MS2 that is a fifth memory string when seen from one side in the Y direction, through the bit line contact BLC0c. Since the bit line BL3 (the fourth bit line) is connected to the memory string MS3 that is a fourth memory string when seen from one side in the Y direction, through the bit line contact BLC0. The bit line BL4 (the fifth bit line) is connected to the memory string MS4 that is a second memory string when seen from one side in the Y direction, through the bit line contact BLC1. Since the bit line BL5 (the sixth bit line) and thereafter repeat the same arrangement shape, the description will not be repeated.

According to the fifth modification example, it is possible to significantly reduce a capacitance of the bit line inter-contact, similar to the embodiment. Accordingly, it is possible to significantly enhance the reliability of the read operation of the data of the memory cell MC in the nonvolatile semiconductor memory device.

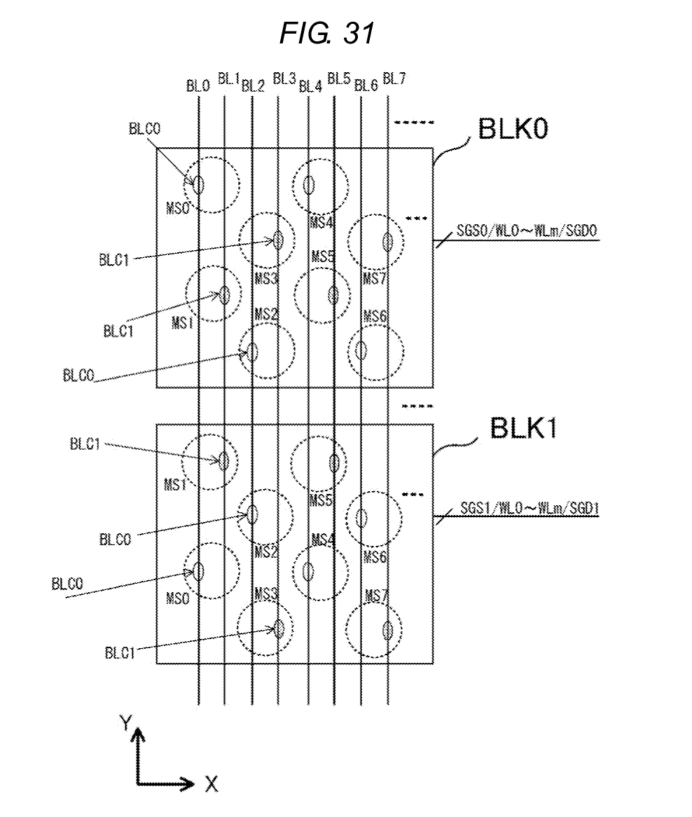

Further, as in a sixth modification example illustrated in FIG. 31, the memory cells MC are connected to the bit line contact BLC0 or the bit line contact BLC1, in units of eight adjacent bit lines BL. The arrangement of the bit line contact BLC0 or the bit line contact BLC1 of the block BLK1 adjacent to the block BLK0 may be changed with respect to the block BLK0.

Specifically, in the block BLK0, the bit line BL0 (the first bit line) is connected to the memory string MS0 that is a first memory string when seen from one side in the Y direction, through the bit line contact BLC0. The bit line BL1 (the second bit line) is connected to the memory string MS1 that is a third memory string when seen from one side in the Y direction, through the bit line contact BLC1. The bit line BL2 (the third bit line) is connected to the memory string MS2 that is a fourth memory string when seen from one side in the Y direction, through the bit line contact BLC0. The bit line BL3 (the fourth bit line) is connected to the memory string MS3 that is a second memory string when seen from one side in the Y direction, through the bit line contact BLC1. The bit line BL4 (the fifth bit line) is connected to the memory string MS4 that is a first memory string when seen from one side in the Y direction, through the bit line contact BLC0. The bit line BL5 (the sixth bit line) is connected to the memory string MS5 that is a third memory string when seen from one side in the Y direction, through the bit line contact BLC1. The bit line BL6 (the seventh bit line) is connected to the memory string MS6 that is a fourth memory string when seen from one side in the Y direction, through the bit line contact BLC0. The bit line BL7 (the eighth bit line) is connected to the memory string MS7 that is a second memory string when seen from one side in the Y direction (the second direction), through the bit line contact BLC1.

On the other hand, in the block BLK1, the bit line BL0 (the first bit line) is connected to the memory string MS0 that is a third memory string when seen from one side in the Y direction, through the bit line contact BLC0. The bit line BL1 (the second bit line) is connected to the memory string MS1 that is a first memory string when seen from one side in the Y direction, through the bit line contact BLC1. The bit line BL2 (the third bit line) is connected to the memory string MS2 that is a second memory string when seen from one side in the Y direction, through the bit line contact BLC0. The bit line BL3 (the fourth bit line) is connected to the memory string MS3 that is a fourth memory string when seen from one side in the Y direction (the second direction), through the bit line contact BLC1. The bit line BL4 (the fifth bit line) is connected to the memory string MS4 that is a third memory string when seen from one side in the Y direction, through the bit line contact BLC0. The bit line BL5 (the sixth bit line) is connected to the memory string MS5 that is a first memory string when seen from one side in the Y direction, through the bit line contact BLC1. The bit line BL6 (the seventh bit line) is connected to the memory string MS6 that is a second memory string when seen from one side in the Y direction, through the bit line contact BLC0. The bit line BL7 (the eighth bit line) is connected to the memory string MS7 that is a fourth memory string when seen from one side in the Y direction (the second direction), through the bit line contact BLC1. Since the bit line BL8 (the ninth bit line) and thereafter repeat the same arrangement shape, the description will not be repeated.

According to the sixth modification example, it is possible to significantly reduce a capacitance of the bit line inter-contact, similar to the embodiment. Accordingly, it is possible to enhance the reliability of the read operation of the data of the memory cell MC in the nonvolatile semiconductor memory device.

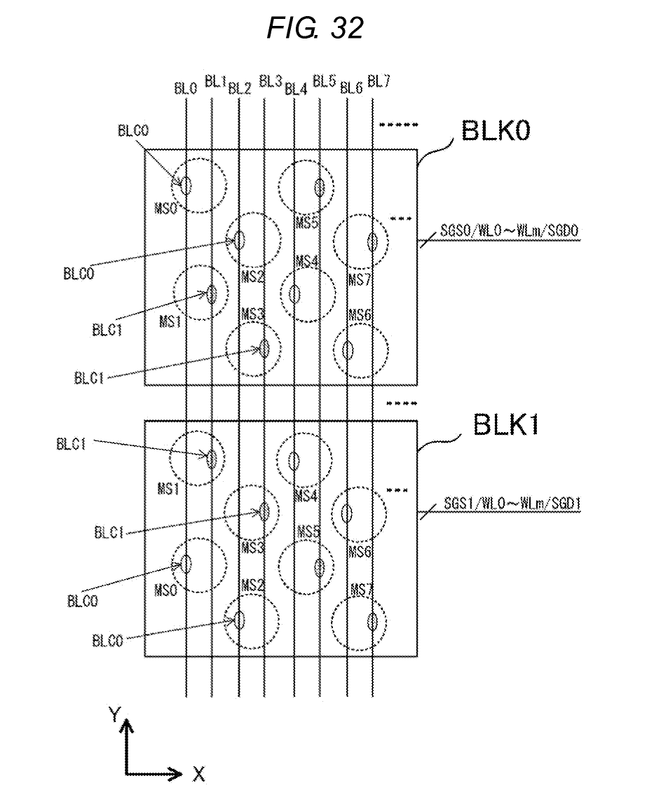

Further, as in the seventh modification example illustrated in FIG. 32, the memory cells MC are connected to the bit line contact BLC0 or the bit line contact BLC1 in units of eight adjacent bit lines BL. The arrangement of the bit line contact BLC0 or the bit line contact BLC1 of the block BLK1 adjacent to the block BLK0 may be changed with respect to the block BLK0.

Specifically, in the block BLK0, the bit line BL0 (the first bit line) is connected to the memory string MS0 that is a first memory string when seen from one side in the Y direction, through the bit line contact BLC0. The bit line BL1 (the second bit line) is connected to the memory string MS1 that is a third memory string when seen from one side in the Y direction, through the bit line contact BLC1. The bit line BL2 (the third bit line) is connected to the memory string MS2 that is a second memory string when seen from one side in the Y direction, through the bit line contact BLC0. The bit line BL3 (the fourth bit line) is connected to the memory string MS3 that is a fourth memory string when seen from one side in the Y direction, through the bit line contact BLC1. The bit line BL4 (the fifth bit line) is connected to the memory string MS4 that is a third memory string when seen from one side in the Y direction, through the bit line contact BLC0. The bit line BL5 (the sixth bit line) is connected to the memory string MS5 that is a first memory string when seen from one side in the Y direction, through the bit line contact BLC1. The bit line BL6 (the seventh bit line) is connected to the memory string MS6 that is a fourth memory string when seen from one side in the Y direction, through the bit line contact BLC0. The bit line BL7 (the eighth bit line) is connected to the memory string MS7 that is a second memory string when seen from one side in the Y direction (the second direction), through the bit line contact BLC1.

On the other hand, in the block BLK1, the bit line BL0 (the first bit line) is connected to the memory string MS0 that is a third memory string when seen from one side in the Y direction, through the bit line contact BLC0. The bit line BL1 (the second bit line) is connected to the memory string MS1 that is a first memory string when seen from one side in the Y direction, through the bit line contact BLC1. The bit line BL2 (the third bit line) is connected to the memory string MS2 that is a fourth memory string when seen from one side in the Y direction, through the bit line contact BLC0. The bit line BL3 (the fourth bit line) is connected to the memory string MS3 that is a second memory string when seen from one side in the Y direction (the second direction), through the bit line contact BLC1. The bit line BL4 (the fifth bit line) is connected to the memory string MS4 that is a first memory string when seen from one side in the Y direction, through the bit line contact BLC0. The bit line BL5 (the sixth bit line) is connected to the memory string MS5 that is a third memory string when seen from one side in the Y direction, through the bit line contact BLC1. The bit line BL6 (the seventh bit line) is connected to the memory string MS6 that is a second memory string when seen from one side in the Y direction, through the bit line contact BLC0. The bit line BL7 (the eighth bit line) is connected to the memory string MS7 that is a fourth memory string when seen from one side in the Y direction (the second direction), through the bit line contact BLC1. Since the bit line BL8 (the ninth bit line) and thereafter repeat the same arrangement shape, the description will not be repeated.

According to the seventh modification example, it is possible to significantly reduce a capacitance of the bit line inter-contact, similar to the embodiment. Accordingly, it is possible to significantly enhance the reliability of the read operation of the data of the memory cell MC in the nonvolatile semiconductor memory device.

In the embodiments and the modification examples, the disclosure is applied to the three-dimensional NAND flash memory, but the disclosure is not necessarily limited thereto. For example, the disclosure may be applied to a three-dimensional semiconductor memory device in which memory strings formed in the Z direction are arranged in a K-line staggering pattern.

The configuration of the memory cell array is disclosed in a “three dimensional stacked nonvolatile semiconductor memory” of U.S. Patent Application Laid-Open No. 2009/0267128 (U.S. patent application Ser. No. 12/407,403). Further, the configuration is disclosed in a “three dimensional stacked nonvolatile semiconductor memory” of U.S. Patent Application Laid-Open No. 2009/0268522 (U.S. patent application Ser. No. 12/406,524), a “non-volatile semiconductor storage device and method of manufacturing the same” of U.S. Patent Application Laid-Open No. 2010/0207195 (U.S. patent application Ser. No. 12/679,991), and a “semiconductor memory and method for manufacturing same” of U.S. Patent Application Laid-Open No. 2011/0284946 (U.S. patent application Ser. No. 12/532,030). These patent applications are incorporated in the specification of the present application by reference.

In each embodiment of the NAND flash memory, (1) in the read operation, a voltage applied to a word line selected in the read operation of a level “A” is, for example, between 0 V and 0.55 V. The voltage is not limited thereto, and may be set to any value between 0.1 V and 0.24 V, between 0.21 V and 0.31 V, between 0.31 V and 0.4 V, between 0.4 V and 0.5 V, and between 0.5 V and 0.55 V.

A voltage applied to a word line selected in the read operation of a level “B” is, for example, between 1.5 V and 2.3 V. The voltage is not limited thereto, and may be set to any value between 1.65 V and 1.8 V, between 1.8 V and 1.95 V, between 1.95 V and 2.1 V, and between 2.1 V and 2.3 V.

A voltage applied to a word line selected in the read operation of a level “C” is, for example, between 3.0 V and 4.0 V. The voltage is not limited thereto, and may be set to any value between 3.0 V and 3.2 V, between 3.2 V and 3.4 V, between 3.4 V and 3.5 V, between 3.5 V and 3.6 V, and between 3.6 V and 4.0 V.

A time (tR) of the read operation may be set between 25 μs and 38 μs, between 38 μs and 70 μs, and between 70 μs and 80 μs.

In each embodiment of the NAND flash memory, (2) the write operation includes a program operation and a verify operation, as described above. In the write operation, a voltage that is initially applied to a word line selected during the program operation is, for example, between 13.7 V and 14.3 V. The voltage is not limited thereto, and for example, may be set to any value between 13.7 V and 14.0 V and between 14.0 V and 14.6 V.

The voltage that is initially applied to the selected word line in writing of an odd-numbered word line may be different from the voltage that is initially applied to the selected word line in writing of an even-numbered word line.

When the program operation uses an incremental step pulse program (ISPP) method, for example, about 0.5 V is used as a step-up voltage.

A voltage applied to an unselected word line, for example, may be between 6.0 V and 7.3 V. The voltage is not limited thereto, and for example, may be set between 7.3 V and 8.4 V, and may be set to 6.0 V or less.

A path voltage to be applied may be changed according to whether the unselected word line is the odd-numbered word line or the even-numbered word line.

A time (tProg) of the write operation may be set between 1,700 μs and 1,800 μs, between 1,800 μs and 1,900 μs, and between 1,900 μs and 2,000 μs, for example.

In each embodiment of the NAND flash memory, (3) in the erase operation, a voltage that is initially applied to a well formed on the semiconductor substrate, on which the memory cell is arranged is between 12 V and 13.6 V, for example. The voltage is not limited thereto, and for example, may be set between 13.6 V and 14.8 V, between 14.8 V and 19.0 V, between 19.0 V and 19.8 V, and between 19.8 V and 21 V.

A time (tErase) of the erase operation may be set between 3,000 μs and 4,000 μs, between 4,000 μs and 5,000 μs, and between 4,000 μs and 9,000 μs, for example.

In each embodiment of the NAND flash memory, (4) the structure of the memory cell has a charge storage layer arranged on the semiconductor substrate (silicon substrate) through a tunnel insulating film having a film thickness of 4 nm to 10 nm. The charge storage layer may have a structure in which an insulating film of SiN or SiON having a film thickness of 2 nm to 3 nm and polysilicon having a film thickness of 3 nm to 8 nm are stacked. A metal such as Ru may be added to the polysilicon. An insulating film is provided on the charge storage layer. The insulating film includes a silicon oxide film having a thickness of 4 nm to 10 nm, which is interposed between a lower High-k film having a thickness of 3 nm to 10 nm and an upper High-k film having a thickness of 3 nm to 10 nm. HfO or the like may be used as the High-k film. Further, the film thickness of the silicon oxide film may be thicker than the film thickness of the High-k film. A control electrode having a film thickness of 30 nm to 70 nm is formed on the insulating film through a work function adjustment material having a film thickness of 3 nm to 10 nm. Here, the work function adjustment material is formed of a metal oxide film such as TaO, or a metal nitride film such as TaN. The control electrode may include a metal such as W.

Further, an air gap may be formed between the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The following configurations may be considered.

(1) A nonvolatile semiconductor memory device including:

a plurality of blocks that extend in a first direction and are provided in parallel with a second direction perpendicular to the first direction, on a plane parallel to a substrate, in which an insulating layer and a conductive layer are alternately and repeatedly stacked to form the blocks;

a plurality of memory strings each of which is formed to penetrate each of the plurality of blocks in a third direction perpendicular to the first and second directions, in which a semiconductor pillar is provided in an inner portion thereof and a memory layer is provided in an outer portion thereof, that includes a memory cell in which a plurality of memory cell transistors are stacked in the third direction, and that are arranged in a K-line (K is an integer of 3 or more) staggering pattern in each of the plurality of blocks;

a plurality of bit line contacts that are respectively provided at an upper portion of the plurality of memory strings;

a plurality of bit lines that are connected to the memory strings through the bit line contacts and are arranged in parallel with the second direction; and

a control circuit that performs a control for sequentially reading data of the memory cells connected to the bit lines in units of adjacent L bit lines (L is an integer of 3 or more).

(2) The nonvolatile semiconductor memory device according to (1), wherein when reading data of the memory cell connected to a selected bit line among the L bit lines, the control circuit shields an unselected bit line to a ground potential.

(3) The nonvolatile semiconductor memory device according to (1) or (2), wherein a sense amplifier is provided on one end side of the bit line, and the sense amplifier shields the unselected bit line based on an instruction of the control circuit.

(4) The nonvolatile semiconductor memory device according to any one of (1) to (3), wherein

the plurality of memory strings has the same shape; the bit line contacts, when the value of n is 4, include two types of bit line contacts of a first bit line contact provided on one side in the first direction and a second bit line contact provided on the other side in the first direction; the plurality of bit lines includes a first bit line to a fourth bit line as one unit; and

the first bit line is connected to the memory string that is a first memory string when seen from one side in the second direction, through the first bit line contact,

the second bit line is connected to the memory string that is a third memory string when seen from one side in the second direction, through the second bit line contact,

the third bit line is connected to the memory string that is a second memory string when seen from one side in the second direction, through the first bit line contact, and

the fourth bit line is connected to the memory string that is a fourth memory string when seen from one side in the second direction, through the second bit line contact.

(5) The nonvolatile semiconductor memory device according to any one of (1) to (3), wherein

the plurality of memory strings has the same shape; the bit line contacts, when the value of n is 4, include two types of bit line contacts of a first bit line contact provided on one side in the first direction and a second bit line contact provided on the other side in the first direction; the plurality of bit lines includes a first bit line to a fourth bit line as one unit; and

the first bit line is connected to the memory string that is a first memory string when seen from one side in the second direction, through the first bit line contact,

the second bit line is connected to the memory string that is a third memory string when seen from one side in the second direction, through the second bit line contact,

the third bit line is connected to the memory string that is a fourth memory string when seen from one side in the second direction, through the first bit line contact, and

the fourth bit line is connected to the memory string that is a second memory string when seen from one side in the second direction, through the second bit line contact.

(6) The nonvolatile semiconductor memory device according to any one of (1) to (3), wherein

the plurality of memory strings has the same shape; the bit line contacts, when the value of n is 4, include two types of bit line contacts of a first bit line contact provided on one side in the first direction and a second bit line contact provided on the other side in the first direction; the plurality of bit lines includes a first bit line to a fourth bit line as one unit; the plurality of blocks includes a first block and a second block that is provided adjacent to the first block, as one unit; and

in the first block,

the first bit line is connected to the memory string that is a first memory string when seen from one side in the second direction, through the first bit line contact,

the second bit line is connected to the memory string that is a third memory string when seen from one side in the second direction, through the second bit line contact,

the third bit line is connected to the memory string that is a second memory string when seen from one side in the second direction, through the first bit line contact, and

the fourth bit line is connected to the memory string that is a fourth memory string when seen from one side in the second direction, through the second bit line contact,

in the second block,

the first bit line is connected to the memory string that is a third memory string when seen from one side in the second direction, through the first bit line contact,

the second bit line is connected to the memory string that is a first memory string when seen from one side in the second direction, through the second bit line contact,

the third bit line is connected to the memory string that is a fourth memory string when seen from one side in the second direction, through the first bit line contact, and

the fourth bit line is connected to the memory string that is a second memory string when seen from one side in the second direction, through the second bit line contact,

(7) The nonvolatile semiconductor memory device according to any one of (1) to (3), wherein

the plurality of memory strings has the same shape; the bit line contacts, when the value of n is 4, include two types of bit line contacts of a first bit line contact provided on one side in the first direction and a second bit line contact provided on the other side in the first direction; the plurality of bit lines includes a first bit line to an eighth bit line as one unit; and

the first bit line is connected to the memory string that is a third memory string when seen from one side in the second direction, through the first bit line contact,

the second bit line is connected to the memory string that is a first memory string when seen from one side in the second direction, through the second bit line contact,

the third bit line is connected to the memory string that is a fourth memory string when seen from one side in the second direction, through the first bit line contact,

the fourth bit line is connected to the memory string that is a second memory string when seen from one side in the second direction, through the second bit line contact,

the fifth bit line is connected to the memory string that is a first memory string when seen from one side in the second direction, through the first bit line contact,

the sixth bit line is connected to the memory string that is a third memory string when seen from one side in the second direction, through the second bit line contact,

the seventh bit line is connected to the memory string that is a second memory string when seen from one side in the second direction, through the first bit line contact, and

the eighth bit line is connected to the memory string that is a fourth memory string when seen from one side in the second direction, through the second bit line contact.

(8) The nonvolatile semiconductor memory device according to any one of (1) to (3), wherein

the plurality of memory strings has the same shape; the bit line contacts, when the value of n is 4, include two types of bit line contacts of a first bit line contact provided on one side in the first direction and a second bit line contact provided on the other side in the first direction; the plurality of bit lines includes a first bit line to a fourth bit line as one unit; a first block group including a plurality of blocks and a second block group including a plurality of blocks are adjacently provided; and

in each block of the first block group,

the first bit line is connected to the memory string that is a first memory string when seen from one side in the second direction, through the first bit line contact,

the second bit line is connected to the memory string that is a third memory string when seen from one side in the second direction, through the second bit line contact,

the third bit line is connected to the memory string that is a second memory string when seen from one side in the second direction, through the first bit line contact, and

the fourth bit line is connected to the memory string that is a fourth memory string when seen from one side in the second direction, through the second bit line contact,

in each block of the second block group,

the first bit line is connected to the memory string that is a third memory string when seen from one side in the second direction, through the first bit line contact,

the second bit line is connected to the memory string that is a first memory string when seen from one side in the second direction, through the second bit line contact,

the third bit line is connected to the memory string that is a fourth memory string when seen from one side in the second direction, through the first bit line contact, and

the fourth bit line is connected to the memory string that is a second memory string when seen from one side in the second direction, through the second bit line contact.

(9) The nonvolatile semiconductor memory device according to any one of (1) to (3), wherein

the plurality of memory strings has the same shape; the bit line contacts, when the value of n is 4, include two types of bit line contacts of a first bit line contact provided on one side in the first direction and a second bit line contact provided on the other side in the first direction; the plurality of bit lines includes a first bit line to an eighth bit line as one unit; the plurality of blocks includes a first block and a second block that is provided adjacent to the first block, as one unit; and

in the first block,

the first bit line is connected to the memory string that is a first memory string when seen from one side in the second direction, through the first bit line contact,

the second bit line is connected to the memory string that is a third memory string when seen from one side in the second direction, through the second bit line contact,

the third bit line is connected to the memory string that is a fourth memory string when seen from one side in the second direction, through the first bit line contact,

the fourth bit line is connected to the memory string that is a second memory string when seen from one side in the second direction, through the second bit line contact,

the fifth bit line is connected to the memory string that is a first memory string when seen from one side in the second direction, through the first bit line contact,

the sixth bit line is connected to the memory string that is a third memory string when seen from one side in the second direction, through the second bit line contact,

the seventh bit line is connected to the memory string that is a fourth memory string when seen from one side in the second direction, through the first bit line contact, and

the eighth bit line is connected to the memory string that is a second memory string when seen from one side in the second direction, through the second bit line contact,

in the second block,

the first bit line is connected to the memory string that is a third memory string when seen from one side in the second direction, through the first bit line contact,

the second bit line is connected to the memory string that is a first memory string when seen from one side in the second direction, through the second bit line contact,

the third bit line is connected to the memory string that is a second memory string when seen from one side in the second direction, through the first bit line contact,

the fourth bit line is connected to the memory string that is a fourth memory string when seen from one side in the second direction, through the second bit line contact,

the fifth bit line is connected to the memory string that is a third memory string when seen from one side in the second direction, through the first bit line contact,

the sixth bit line is connected to the memory string that is a first memory string when seen from one side in the second direction, through the second bit line contact,

the seventh bit line is connected to the memory string that is a second memory string when seen from one side in the second direction, through the first bit line contact, and

the eighth bit line is connected to the memory string that is a fourth memory string when seen from one side in the second direction, through the second bit line contact.

(10) The nonvolatile semiconductor memory device according to any one of (1) to (3), wherein

the plurality of memory strings has the same shape; the bit line contacts, when the value of n is 4, include two types of bit line contacts of a first bit line contact provided on one side in the first direction and a second bit line contact provided on the other side in the first direction; the plurality of bit lines includes a first bit line to an eighth bit line as one unit; the plurality of blocks includes a first block and a second block that is provided adjacent to the first block, as one unit; and

in the first block,

the first bit line is connected to the memory string that is a first memory string when seen from one side in the second direction, through the first bit line contact,

the second bit line is connected to the memory string that is a third memory string when seen from one side in the second direction, through the second bit line contact,

the third bit line is connected to the memory string that is a second memory string when seen from one side in the second direction, through the first bit line contact,

the fourth bit line is connected to the memory string that is a fourth memory string when seen from one side in the second direction, through the second bit line contact,

the fifth bit line is connected to the memory string that is a third memory string when seen from one side in the second direction, through the first bit line contact,

the sixth bit line is connected to the memory string that is a first memory string when seen from one side in the second direction, through the second bit line contact,

the seventh bit line is connected to the memory string that is a fourth memory string when seen from one side in the second direction, through the first bit line contact, and

the eighth bit line is connected to the memory string that is a second memory string when seen from one side in the second direction, through the second bit line contact,

in the second block,

the first bit line is connected to the memory string that is a third memory string when seen from one side in the second direction, through the first bit line contact,

the second bit line is connected to the memory string that is a first memory string when seen from one side in the second direction, through the second bit line contact,

the third bit line is connected to the memory string that is a fourth memory string when seen from one side in the second direction, through the first bit line contact,

the fourth bit line is connected to the memory string that is a second memory string when seen from one side in the second direction, through the second bit line contact,

the fifth bit line is connected to the memory string that is a first memory string when seen from one side in the second direction, through the first bit line contact,

the sixth bit line is connected to the memory string that is a third memory string when seen from one side in the second direction, through the second bit line contact,

the seventh bit line is connected to the memory string that is a second memory string when seen from one side in the second direction, through the first bit line contact, and

the eighth bit line is connected to the memory string that is a fourth memory string when seen from one side in the second direction, through the second bit line contact.

What is claimed is:

1. A nonvolatile semiconductor memory device comprising:
a plurality of memory cells including a first memory cell, a second memory cell, and a third memory cell;
a plurality of bit lines including a first bit line coupled to the first memory cell, a second bit line coupled to the second memory cell, and a third bit line coupled to the third memory cell; and
a control circuit configured to perform a control for reading data from the first, second, and third memory cells such that when one of the first, second, and third memory cells is selected for reading, the other memory cells are not selected for reading.

2. The device according to claim 1, wherein
the control circuit is configured to select the first bit line when reading data from the first memory cell, the second bit line when reading data from the second memory cell, and the third bit line when reading data from the third memory cell.

3. The device according to claim 2, wherein
the control circuit, when reading data from one of the first, second, and third memory cells, sets the bit lines coupled to the other memory cells to a ground potential.

4. The device according to claim 3, further comprising:
a sense amplifier provided for each of the bit lines, and
the sense amplifier connects the bit lines coupled to the other memory cells to the ground potential after receiving an instruction from the control circuit.

5. The device according to claim 1, wherein the bit lines extend in a direction and are parallel to each other, and the first and second bit lines and the second and third bit lines, are adjacent to each other.

6. The device according to claim 5, wherein the memory cells are above a semiconductor substrate and extend away from the substrate along a first direction, the first and second memory cells being aligned along a second direction that is orthogonal to the first direction and the third memory cell not being aligned with the first and second memory cells along the second direction.

7. The device according to claim 6, wherein each of the memory cells is coupled to a corresponding bit line through a bit line contact and positions of the bit line contacts of the first, second, and third memory cells are not aligned along the second direction.

8. The device according to claim 1, wherein
the memory cells further include a fourth memory cell and the bit lines further include a fourth bit line coupled to the fourth memory cell, and
the bit lines extend in a direction and are parallel to each other, and the first and second bit lines, the second and third bit lines, and the third and fourth bit lines, are adjacent to each other.

9. The device according to claim 8, wherein the memory cells are above a semiconductor substrate and arranged away from the substrate along a first direction, the first and second memory cells being aligned along a second direction that is orthogonal to the first direction and the third and fourth memory cells being aligned along the second direction and offset with respect to the first and second memory cells in a third direction that is orthogonal to the first and second directions.

10. The device according to claim 9, wherein each of the memory cells is coupled to a corresponding bit line through a bit line contact and positions of the bit line contacts of the first, second, third, and fourth memory cells are not aligned along the second direction.

11. The device according to claim 1, further comprising:
a first block including the first memory cell, the second memory cell and the third memory cell; and
a second block including a fourth memory cell, a fifth memory cell and the sixth memory cell,
wherein the first bit line is coupled to the fourth memory cell, the second bit line is coupled to the fifth memory cell, and the third bit line is coupled to the sixth memory cell, a first bit line contact between the first bit line and the first memory cell is in a first region of the first block, a second bit line contact between the first bit line and the fourth memory cell is in a second region of the second block, and the first region is different from the second region.

12. The device according to claim 10, wherein the fourth memory cell is between the first and second memory cells along the second direction.

13. The device according to claim 8, wherein the control circuit is configured to perform a control for reading data from the first, second, third, and fourth memory cells such that when one of the first, second, third, and fourth memory cells is selected for reading, the other memory cells are not selected for reading.

14. A nonvolatile semiconductor memory device comprising:
a plurality of memory blocks including first and second memory blocks that are adjacent to each other, each of the memory blocks including a first memory cell, a second memory cell, and a third memory cell;
a plurality of bit lines including a first bit line coupled to the first memory cell of each memory block, a second bit line coupled to the second memory cell of each memory block, and a third bit line coupled to the third memory cell of each memory block; and
a control circuit configured to perform a control for reading data from the first, second, and third memory cells of each memory block such that when one of the first, second, and third memory cells of each memory block is selected for reading, the other memory cells among the first, second, and third memory cells of each memory block are not selected for reading.

15. The device according to claim 14, wherein
each of the memory blocks further includes a fourth memory cell and the bit lines further include a fourth bit line coupled to the fourth memory cell of each memory block, and
the bit lines extend in a direction and are parallel to each other, and the first and second bit lines, the second and third bit lines, and the third and fourth bit lines, are adjacent to each other.

16. The device according to claim 15, wherein the memory cells are above a semiconductor substrate and arranged away from the substrate along a first direction, the first and second memory cells of all of the memory blocks being aligned along a second direction that is orthogonal to the first direction and the third and fourth memory cells of all of the memory blocks being aligned along the second direction and offset with respect to the first and second memory cells in a third direction that is orthogonal to the first and second directions.

17. The device according to claim 16, wherein each of the memory cells is coupled to a corresponding bit line through a bit line contact and positions of the bit line contacts of the first, second, third, and fourth memory cells in each memory block are not aligned along the second direction.

18. The device according to claim 17, wherein the third memory cell of the first memory block is between the first and second memory cells of the first memory block along the second direction and the third memory cell of the second memory block is between the first and second memory cells of the second memory block along second direction.

19. The device according to claim 17, wherein the third memory cell of the first memory block is between the first and second memory cells of the first memory block along the second direction and the fourth memory cell of the second memory block is between the first and second memory cells of the second memory block along second direction.

20. A method of reading data from memory cells of a nonvolatile semiconductor memory device, the memory cells including a first memory cell, a second memory cell, and a third memory cell, and coupled to a corresponding bit line, said method comprising:
selecting a first bit line coupled to the first memory cell to read from the first memory cell; and
while the first bit line is selected, setting a second bit line coupled to the second memory cell and third bit line coupled to the third memory cell to a ground potential,
wherein the first and second bit lines are adjacent to each other and the second and third bits lines are adjacent to each other.
